(19) United States
(12) Patent Application Publication
(10) Pub. No.: US 2014/0169069 A1
(43) Pub. Date: Jun. 19, 2014

(54) Resistive Memory Device, System Including the Same and Method of Reading Data in the Same

(71) Applicant: Hyung-Rok Oh, Yongin-si (KR)

(72) Inventor: Hyung-Rok Oh, Yongin-si (KR)

(21) Appl. No.: 14/094,021

(22) Filed: Dec. 2, 2013

(30) Foreign Application Priority Data
Dec. 18, 2012 (KR) 10-2012-0148036

(51) Int. Cl. G11C 13/00

(52) U.S. Cl. CPC G11C 13/004
USPC 365/148

(57) ABSTRACT

A resistive memory device includes a memory cell array, a memory interface and a read sensing circuit. The memory cell array includes a plurality of resistive memory cells coupled to a plurality of wordlines and a plurality of bitlines. The memory interface is configured to communicate with a memory controller. The read sensing circuit is coupled to the bitlines and includes at least one sensing node. The read sensing circuit performs a precharge operation to precharge the at least one sensing node between a first time point of receiving an active command through the memory interface and a second time point of receiving a read command through the memory interface, and senses data stored in the resistive memory cells to provide read data.

### CROSS-REFERENCE TO RELATED APPLICATION

This U.S. Non-provisional application claims priority under 35 USC §119 to Korean Patent Application No. 10-2012-0148036, filed on Dec. 18, 2012, in the Korean Intellectual Property Office (KIPO), the disclosure of which is incorporated by reference in its entirety herein.

### FIELD

Example embodiments relate generally to memory devices, and more particularly to a resistive memory device capable of performing a hidden precharge operation, a system including a resistive memory device and a method of reading data in a resistive memory device.

### BACKGROUND

Semiconductor memory devices for storing data may be classified into volatile memory devices and non-volatile memory devices. Volatile memory devices, such as dynamic random access memory (DRAM) devices, are typically configured to store data by charging or discharging capacitors in memory cells, and lose the stored data when power is off. Non-volatile memory devices, such as flash memory devices, may maintain stored data even though power is off. Volatile memory devices are widely used as main memories of various apparatuses, while non-volatile memory devices are widely used for storing program code and/or data in various electronic devices, such as computers, mobile devices, etc.

Due to demand for high memory capacity, high operation speed and low power consumption of the memory devices, resistive memories of various types have been developed in an attempt to combine the high integration rate and high speed of DRAM devices and the non-volatility of flash memory devices in a single memory device. Materials used in resistive memory devices have a resistance that is variable depending on magnitude and/or direction of applied voltage and/or current. Moreover, the resistance of the material can be maintained (that is, non-volatility) even though the applied voltage and/or current is removed and thus a refresh operation may not be required.

To use a resistive memory as a main memory, it is desirable to enhance the operation speed, reliability of write and read operations, and/or compatibility of the memory for communicating with the conventional memory controllers, etc.

### SUMMARY

At least one example embodiment of the inventive concept provides a resistive memory device having an enhanced operational speed and reliability of a read operation.

At least one example embodiment of the inventive concept provides a system including the resistive memory device.

At least one example embodiment of the inventive concept provides a method of reading data in the resistive memory device.

According to example embodiments, a resistive memory device includes a memory cell array, a memory interface and a read sensing circuit. The memory cell array includes a plurality of resistive memory cells coupled to a plurality of wordlines and a plurality of bitlines. The memory interface is configured to communicate with a memory controller. The read sensing circuit is coupled to the bitlines and includes at least one sensing node. The read sensing circuit performs a precharge operation to precharge the at least one sensing node between a first time point of receiving an active command through the DRAM interface and a second time point of receiving a read command through the DRAM interface, and senses data stored in the resistive memory cells to provide read data.

The DRAM interface may include input pads receiving a row address strobe (RAS) signal and a column address strobe (CAS) signal.

The resistive memory cell may include a phase change random access memory (PRAM) cell, a resistance random access memory (RRAM) cell or a magneto-resistive random access memory (MRAM) cell.

The resistive memory cell may include spin-torque transfer magneto-resistive random access memory (STT-MRAM) cell.

The resistive memory device may further includes a precharge control circuit configured to generate a precharge signal that is activated in response to the active command and deactivated in response to the read command.

The read sensing circuit may include a local sensing node, a precharge circuit and a sense amplifier. The local sensing node is electrically coupled to a selected bitline via a column selection circuit, where the selected bitline is selected among the bitlines in response to a column address. The precharge circuit may precharge the local sensing node in response to the precharge signal. The sense amplifier may, after the selected bitline is electrically coupled to the local sensing node, sense a voltage or a current on the local sensing node to output the read data.

The read sensing circuit may further include a clamp circuit coupled between the selected bitline and the local sensing node.

The read sensing circuit may further include a bias circuit configured to apply a bias current to the local sensing node at a time point when the selected bitline is electrically coupled to the local sensing node.

The read sensing circuit may include a plurality of bitline sensing units respectively coupled to the bitlines.

The bitline sensing units may perform a page open operation in which the bitline sensing units sense and simultaneously latch a plurality of data bits that are stored in the resistive memory cells commonly coupled to a selected wordline, where the selected wordline is among the wordlines in response to a row address.

Each of the bitline sensing unit may include a bitline sensing node; a develop switch configured to electrically couple the corresponding bitline to the bitline sensing node in response to a develop control signal; a precharge circuit configured to precharge the bitline sensing node in response to the precharge signal; and a sense amplifier configured to, after the selected bitline is electrically coupled to the bitline sensing node, sense a voltage or a current on the bitline sensing node to latch a bit of the read data.

The resistive memory device may further include a precharge control circuit configured to generate a first precharge signal and a second precharge signal, the first precharge signal being activated in response to the active command and deactivated in response to a first read command, the first precharge signal being repeatedly activated and deactivated in response to other read commands that are sequentially received after the first read command, the second precharge signal being activated and deactivated complementarily with the first precharge signal.

The read sensing circuit may include a first read sensing circuit configured to perform the precharge operation in response to the first precharge signal; and a second read sensing circuit configured to perform the precharge operation in response to the second precharge signal.

One of the first read sensing circuit and the second read sensing circuit may be selected in response to a first column selection enable signal and a second column selection enable signal that are activated complementarily with each other, and the selected one of the first read sensing circuit and the second read sensing circuit may be electrically coupled to a selected bitline, where the selected bitline is selected among the bitlines in response to a column address.

According to example embodiments, a system includes a memory controller, and a resistive memory device configured to communicate with the memory controller according to a dynamic random access memory (DRAM) standard. The resistive memory device includes a memory cell array including a plurality of resistive memory cells coupled to a plurality of wordlines and a plurality of bitlines; a DRAM interface configured to communicate with the memory controller; and a read sensing circuit coupled to the bitlines and comprising at least one sensing node, the read sensing circuit configured to perform a precharge operation to precharge the at least one sensing node between a first time point of receiving an active command through the DRAM interface and a second time point of receiving a read command through the DRAM interface, and configured to sensing data stored in the resistive memory cells to provide read data.

The resistive memory device may further include a precharge control circuit configured to generate a precharge signal that is activated in response to the active command and deactivated in response to the read command. The read sensing circuit may perform the precharge operation in response to the precharge signal.

The system may further include a DRAM device including a plurality of DRAM cells. The DRAM device may share at least a portion of the DRAM interface with the resistive memory device.

The DRAM device may be enabled in response to a first chip selection signal and the resistive memory device may be enabled in response to a second chip selection signal.

The resistive memory cell may include a phase change random access memory (PRAM) cell, a resistance random access memory (RRAM) cell or a magneto-resistive random access memory (MRAM) cell.

According to example embodiment, provided is a method of reading data in a resistive memory device including a plurality of resistive memory cells coupled respectively to a plurality of wordlines and a plurality of bitlines. The method includes receiving an active command and a read command from a memory controller according to a dynamic random access memory (DRAM) standard; precharging at least one sensing node between a time point of receiving the active command and a time point of receiving the read command; electrically coupling the at least one sensing node with at least one bitline among the plurality of bitlines; and sensing a voltage or a current on the at least one sensing node to provide read data.

Precharging the at least one sensing node may include activating a precharge signal in response to the active command; and deactivating the precharge signal in response to the read command.

Precharging the at least one sensing node may further include precharging a local sensing node in response to the precharge signal, the local sensing node being commonly coupled to the bitlines.

Precharging the at least one sensing node may further include precharging a plurality of bitline sensing nodes simultaneously in response to the precharge signal, the bitline sensing nodes being coupled to the respective bitlines.

The resistive memory device may include a DRAM interface configured to communicate with the memory controller and the DRAM interface may include input pads receiving a row address strobe (RAS) signal and a column address strobe (CAS) signal.

### BRIEF DESCRIPTION OF THE DRAWINGS

Example embodiments of the inventive concept will be more clearly understood from the following detailed description taken in conjunction with the accompanying drawings.

FIG. 1 is a flowchart illustrating a method of reading data in a resistive memory device according to example embodiments.

FIG. 2 is a diagram illustrating a memory system including a resistive memory device according to example embodiments.

FIGS. 3, 4 and 5 are diagrams for describing commands of dynamic random access memory (DRAM) standard, which are provided to a resistive memory device according to example embodiments.

FIG. 6 is a block diagram illustrating a resistive memory device according to example embodiments.

FIG. 7 is a circuit block diagram illustrating a resistive memory device according to an example embodiment.

FIG. 8 is a circuit diagram illustrating an example embodiment of a read sensing circuit in the resistive memory device of FIG. 7.

FIG. 9 is a diagram illustrating a timing control circuit that generates a precharge signal according to an example embodiment.

FIG. 10 is a timing diagram illustrating an operation of a resistive memory device according to an example embodiment.

FIG. 11 is a diagram for describing a read sequence in a method of reading data according to example embodiments.

FIG. 12 is a block diagram illustrating a resistive memory device including a plurality of memory banks according to an example embodiment.

FIG. 13 is a diagram illustrating an example of a resistive memory cell in a memory cell array.

FIG. 14 is a diagram illustrating another example of a resistive memory cell in a memory cell array.

FIG. 15 a diagram illustrating an example of a unipolar resistive element in the resistive memory cell of FIGS. 13 and 14.

FIG. 16 a diagram illustrating an example of a bipolar resistive element in the resistive memory cell of FIG. 14.

FIG. 17 is a diagram illustrating an example of a spin-transfer torque magneto-resistive random access memory (STT-MRAM) cell in the memory cell array of FIG. 6.

FIGS. 18 and 19 are diagrams illustrating magnetization directions of a magnetic tunnel junction (MTJ) element depending on written data.

FIG. 20 is a diagram for describing a write operation of the STT-MRAM cell.

FIGS. 21 through 25 are diagrams illustrating examples of the MTJ element in the STT-MRAM cell.

FIG. 26 is a circuit diagram illustrating a resistive memory device according to an example embodiment.

FIG. 27 is a diagram illustrating a timing control circuit that generates a precharge signal according to an example embodiment.

FIG. 28 is a timing diagram illustrating an operation of a resistive memory device according to an example embodiment.

FIG. 29 is a circuit diagram illustrating a resistive memory device according to an example embodiment.

FIG. 30 is a circuit diagram illustrating an example embodiment of a read sensing circuit in the resistive memory device of FIG. 29.

FIG. 31 is a diagram illustrating a timing control circuit that generates a precharge signal according to an example embodiment.

FIG. 32 is a timing diagram illustrating an operation of a resistive memory device according to an example embodiment.

FIG. 33 is a diagram illustrating a system including a resistive memory device according to example embodiments.

FIGS. 34 and 35 are block diagrams illustrating systems in which a memory device and a memory controller are coupled through optical links, according to example embodiments.

FIGS. 36 and 37 are block diagrams illustrating computing systems including a resistive memory device according to example embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

FIG. 1 is a flowchart illustrating a method of reading data in a resistive memory device according to example embodiments.

A method of reading data stored in a resistive memory device is described with reference to FIG. 1. The resistive memory device includes a plurality of resistive memory cells coupled respectively to a plurality of wordlines and a plurality of bitlines.

Referring to FIG. 1, an active command ACT and a read command RD are received by the resistive memory device from a memory controller according to a dynamic random access memory (DRAM) standard (S100). According to the DRAM standard, the active command ACT is received and then the read command RD after a predetermined RAS-to-CAS delay time tRCD. The memory controller receives a row address with the active command ACT and performs row address strobe (RAS) addressing based on the row address to select a wordline among the plurality of wordlines. After the RAS addressing, the memory controller receives a column address with the read command RD and performs column address strobe (CAS) addressing based on the column address to select at least one bitline among the plurality of bitlines.

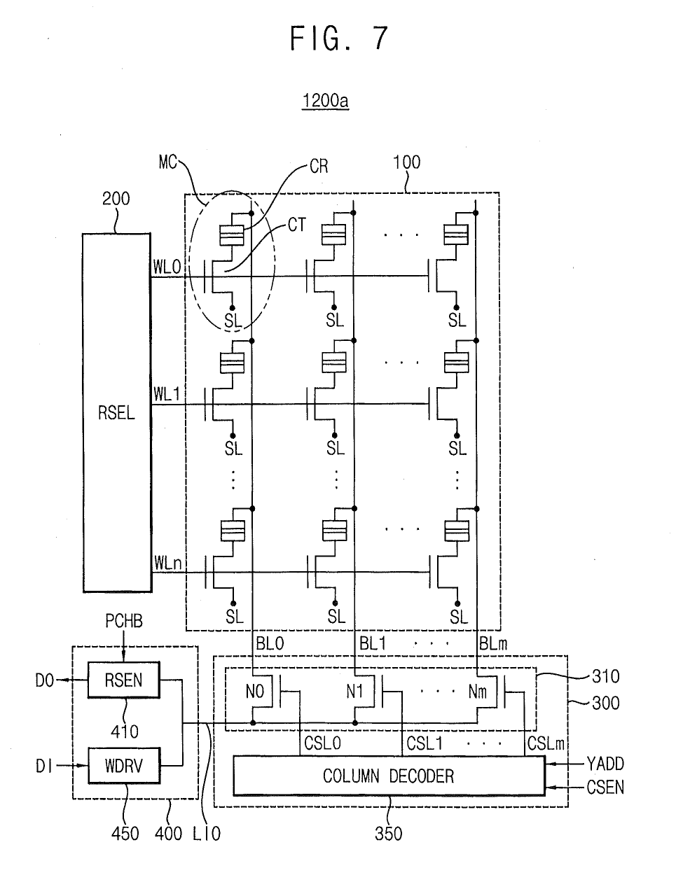

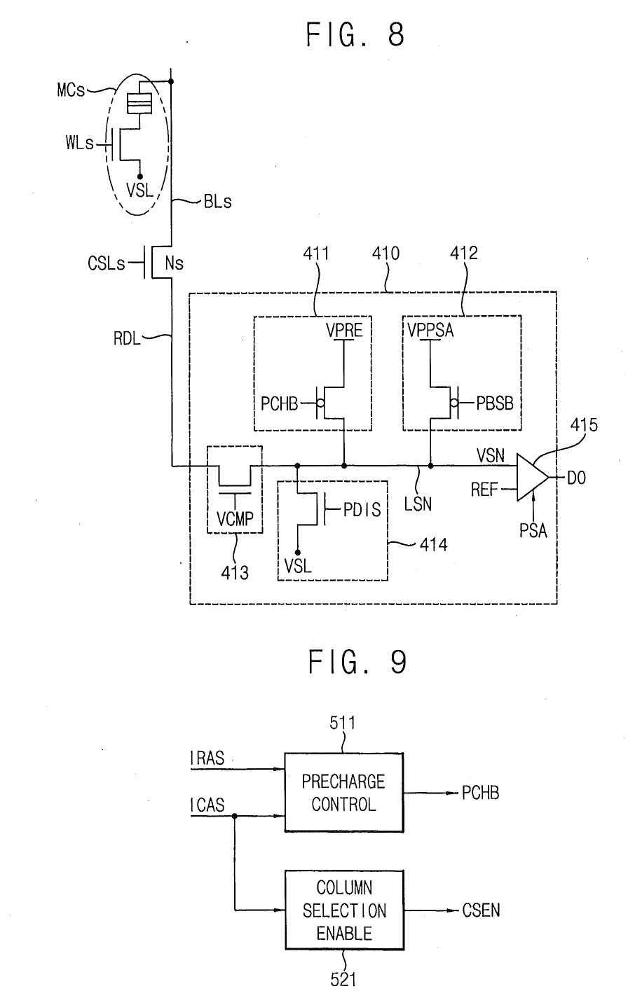

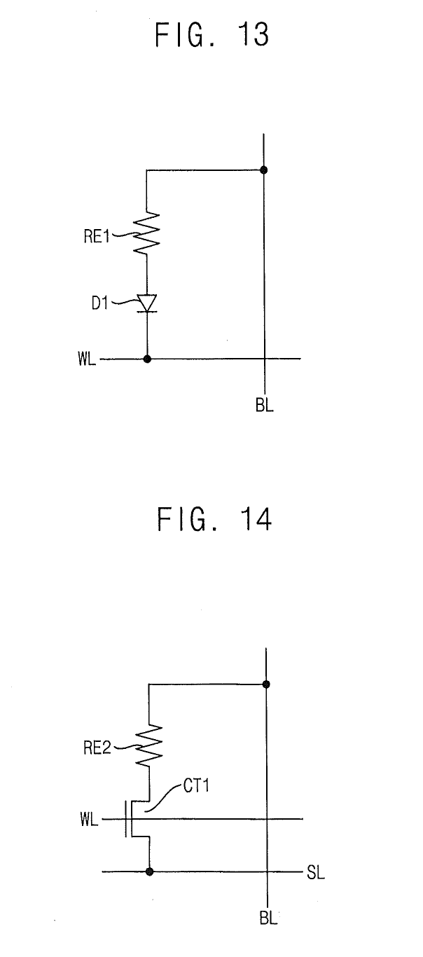

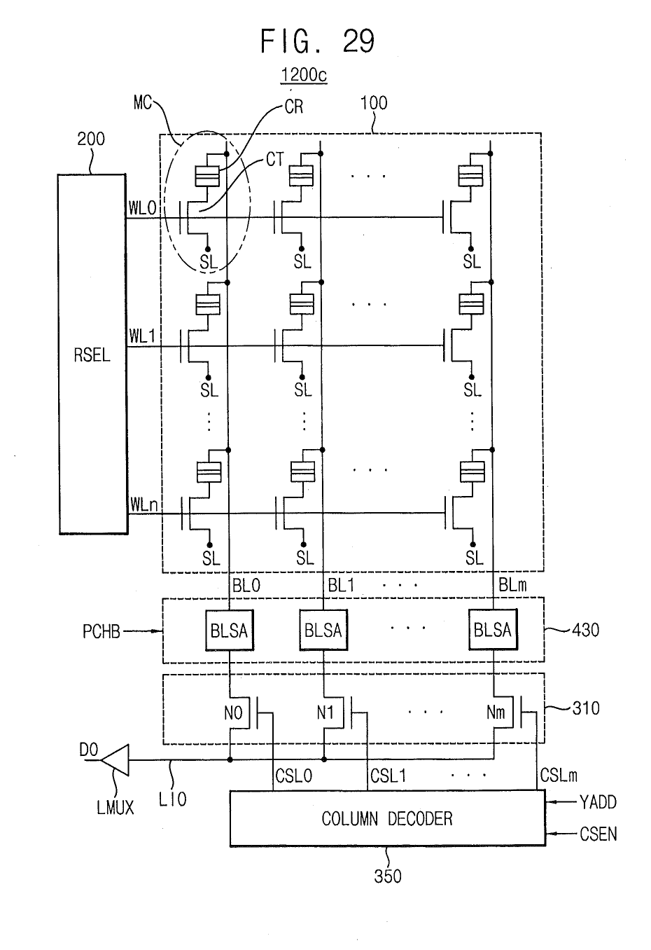

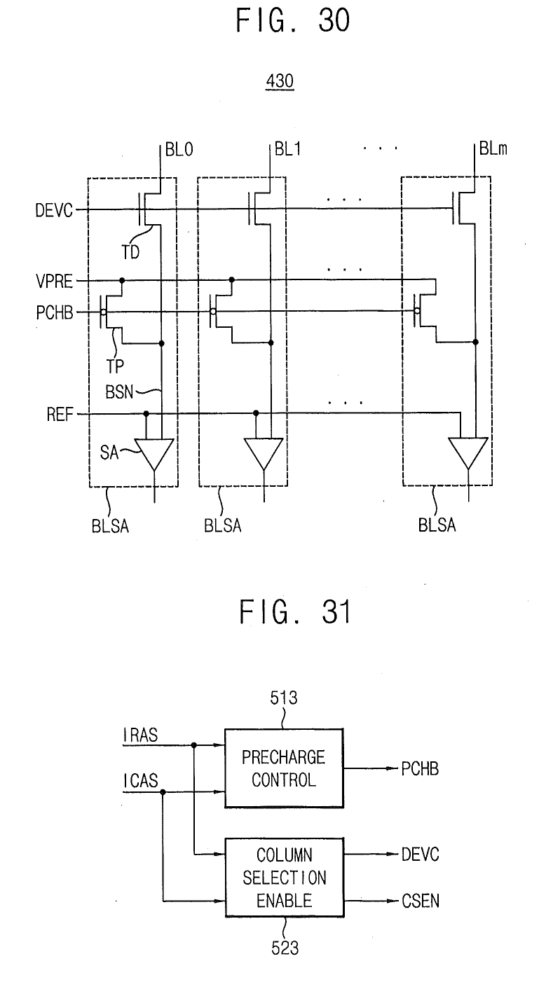

At least one sensing node is precharged between a first time point of receiving an active command and a second time point of receiving a read command (S200). The number of the sensing nodes that are precharged simultaneously may be determined depending on the configuration of the resistive memory device. For example, one local sensing node LSN in the read sensing circuit 410 may be precharged in case of a configuration illustrated in FIGS. 7 and 8, or a plurality of bitline sensing nodes BSNs in a plurality of bitline sensing units BLSAs may be precharged simultaneously in case of a configuration illustrated in FIGS. 29 and 30. If the resistive memory device has a configuration as illustrated in FIG. 12, a plurality of local sensing nodes corresponding to memory blocks in one memory bank may be precharged simultaneously.

The at least one sensing node is electrically coupled with at least one bitline among the plurality of bitlines (S300). Through the electrical connection, the precharged sensing node is developed with a current or a voltage corresponding to a resistance of a selected resistive memory cell that is coupled to the selected wordline and the selected bitline.

The voltage or the current on the at least one sensing node is sensed to provide read data (S400). According to a configuration of the read sensing circuit, a voltage sensing or a current sensing may be performed, and the read data corresponding to the resistance of the selected resistive memory cell may be provided.

As such, a hidden precharge operation may be performed using the RAS-to-CAS delay time tRCD between the time point of receiving the active command ACT and the time point of receiving the read command RD. Through the hidden precharge operation, the speed of the read operation may be increased and/or the reliability of the read data may be enhanced by increasing the sensing margin.

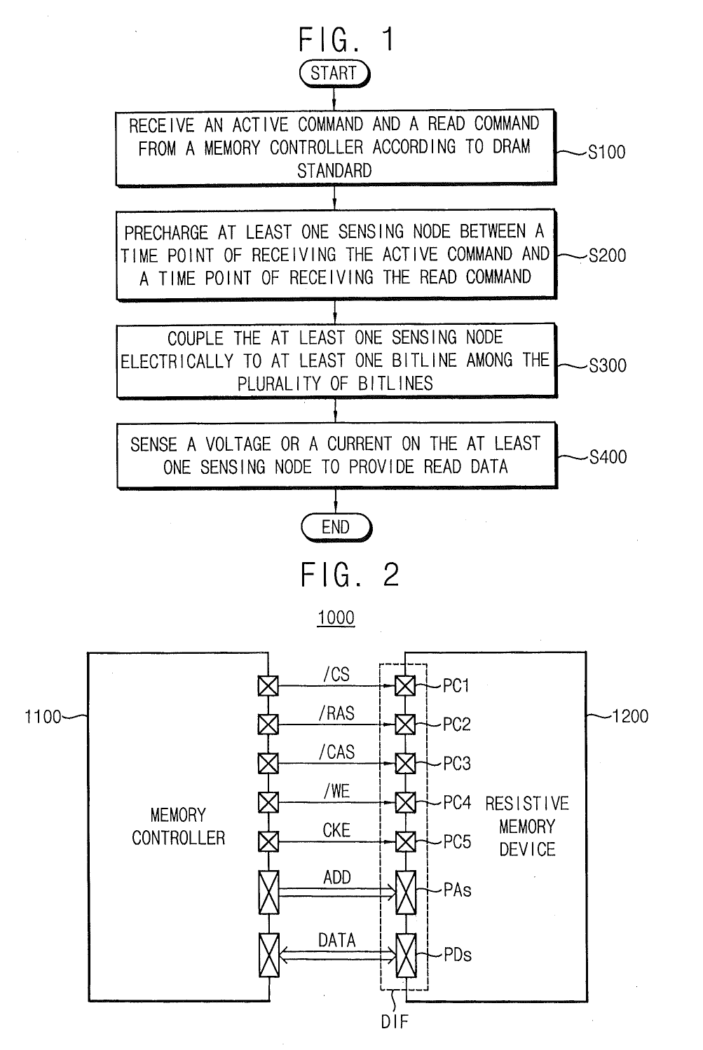

FIG. 2 is a diagram illustrating a memory system including a resistive memory device according to example embodiments.

Referring to FIG. 2, a memory system 1000 includes a memory controller 1100 and a resistive memory device 1200. The resistive memory device 1200 includes a DRAM interface DIF for communicating with the memory controller 1100. The DRAM interface DIF may include control pads (or pins) PC1 through PC5, address pads PAs and data pads PDs. The resistive memory device 1200 may receive control signals such as a chip selection signal /CS, a row address strobe signal /RAS, a column address strobe signal /CAS, a write enable signal /WE, a clock enable signal CKE, etc through the control pads PC1 through PC5. The resistive memory device 1200 may receive the address signal ADD through the address pads PAs, and receive the write data or transmit the read data through the data pads PDs.

Even though the DRAM interface DIF may be implemented in many ways according to the DRAM standard, the DRAM interface DIF includes at least the pads directly related with the timing of the hidden precharge operation according to example embodiments. In other words, the DRAM interface DIF includes at least the pads PC2 and PC3 receiving the RAS signal /RAS and the CAS signal /CAS. Even though not illustrated in FIG. 2, the DRAM interface DIF may further include pads for receiving a clock signal, a power supply voltage, etc.

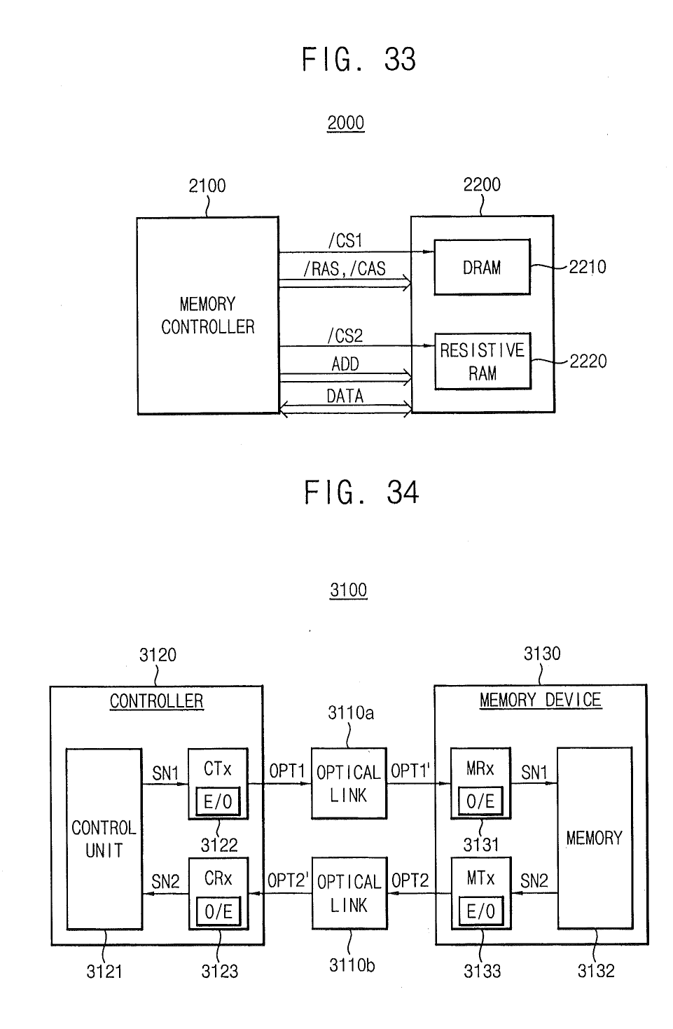

The resistive memory device 1200 and the system 1000 may be implemented with the existing DRAM interface, and thus the resistive memory device 1200 may be used as a main memory without excessive design change. A resistive memory device as illustrated in FIG. 2 may be used as a main memory instead of a DRAM device, or the resistive memory device may be further included as the main memory in addition to the DRAM device as illustrated in FIG. 33.

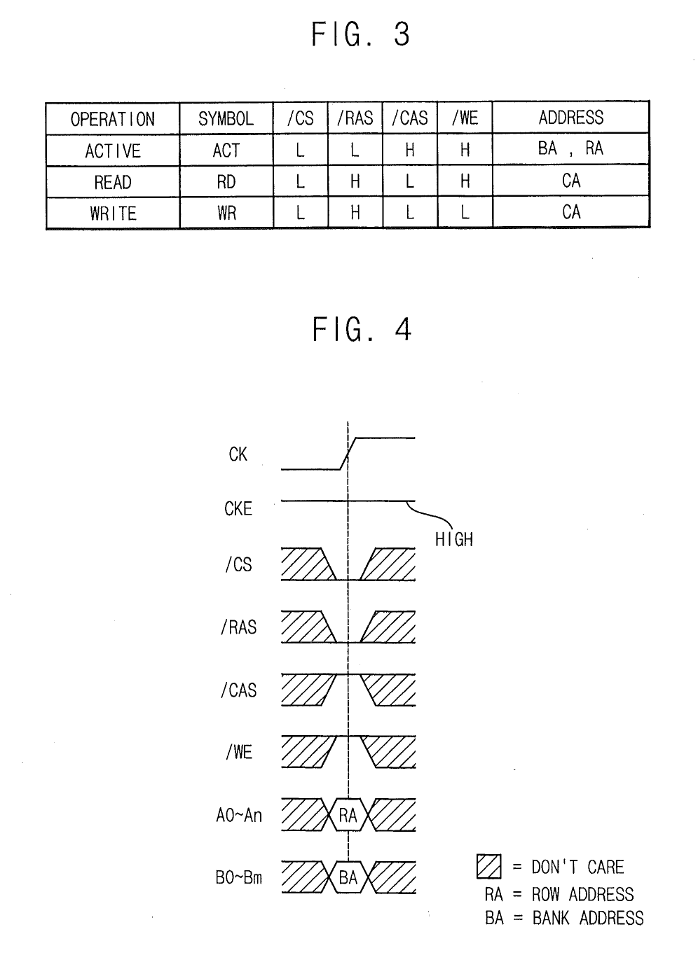

FIGS. 3, 4 and 5 are diagrams for describing commands of dynamic random access memory (DRAM) standard, which are provided to a resistive memory device according to example embodiments.

FIG. 3 illustrates a portion of the command truth table according to the DRAM standard for convenience of illustration, which includes some commands for describing the example embodiments. As illustrated in FIG. 3, the active command ACT, the read command RD, the write command WR, etc. may be represented by combinations of logic levels H and L of the control signals /CS, /RAS, /CAS and /WE. The resistive memory device 1200 in FIG. 2 may receive the bank address BA and the row address RA with the active command ACT from the memory controller 1100 to perform the RAS addressing for selecting the memory bank and the wordline. In addition, resistive memory device 1200 may receive the column address CA with the read command RD or the write command WR from the memory controller 1100 to perform the CAS addressing for selecting the bitline.

FIG. 4 illustrates the combination of the control signals CKE, /CS, /RAS, /RAS and /WE corresponding to the active command ACT. For example, the resistive memory device 1200 may determine in response to a rising edge of the clock single CK that the active command ACT is received when the logic levels of the control signals CKE, /CS, /RAS, /RAS and /WE are as illustrated in FIG. 4.

The resistive memory device 1200 may, with the active command ACT, receive the row address RA and the bank address BA through the address pins A0˜An and the bank address pins B0˜Bm. When the resistive memory device 1200 includes a signal memory bank, the bank address pins B0˜Bm and the bank address BA may be omitted.

Before the read command RD or the write command WR is issued, one memory bank corresponding to the bank address BA and one row (e.g., wordline) corresponding to the row address RA have to be opened. Such RAS addressing may be performed in response to the transfer of the active command ACT.

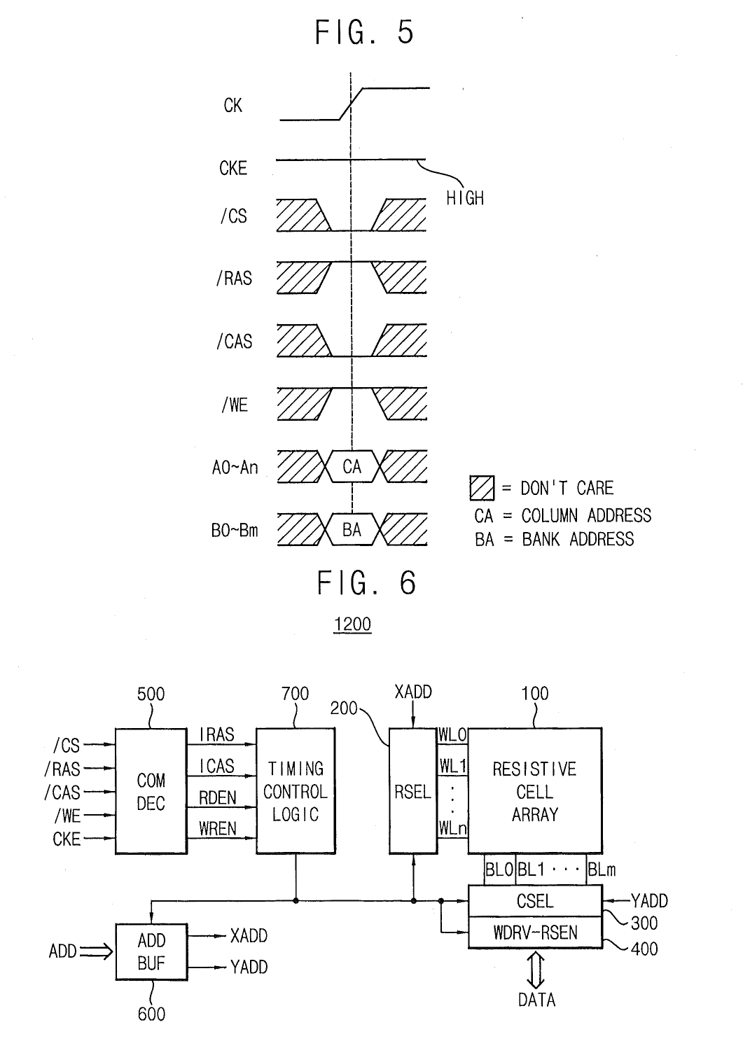

FIG. 5 illustrates the combination of the control signals CKE, /CS, /CAS, /RAS and /WE corresponding to the read command RD. For example, the resistive memory device 1200 may determine in response to a rising edge of the clock single CK that the read command RD is received when the logic levels of the control signals CKE, /CS, /CAS, /RAS and /WE are as illustrated in FIG. 5.

The resistive memory device 1200 may, with the read command RD, receive the column address CA and the bank address BA through the address pins A0˜An and the bank address pins B0˜Bm. The transfer of the bank address BA may be omitted in case of the read command RD.

One column (e.g., bitline) corresponding to the column address CA has to be opened with respect to the row opened by the active command ACT. Such CAS addressing may be performed in response to the transfer of the read command RD.

Through such RAS addressing and CAS addressing, at least one memory cell may be selected or accessed among a plurality of memory cells, and the data stored in the selected memory cell may be sensed.

As described above, the hidden precharge operation may be performed using the RAS-to-CAS delay time tRCD between the time point of receiving the active command ACT as illustrated in FIG. 4 and the time point of receiving the read command RD as illustrated in FIG. 5. Through the hidden precharge operation, the speed of the read operation may be increased and the reliability of the read data may be enhanced by increasing the sensing margin.

FIG. 6 is a block diagram illustrating a resistive memory device according to example embodiments.

Referring to FIG. 6, a resistive memory device 1200 may include a resistive cell array 100, a row selection circuit (RSEL) 200, a column selection circuit (CSEL) 300, an input-output circuit 400, a command decoder (COM DEC) 500, an address buffer (ADD BUF) 600 and a timing control logic 700. The input-output circuit 400 may include a write driver WDRV and a read sensing circuit RSEN.

The resistive cell array 100 includes a plurality of resistive memory cells respectively coupled to a plurality of wordlines WL0 through WLn and a plurality of bitlines BL0 through BLm. The resistive memory cell may have relatively a lower resistance value or a higher resistance value depending on the written data. The embodiments of the resistive memory cell are described with reference to FIGS. 13 through 25.

The command decoder 500 generate internal command signals such as an internal RAS signal IRAS, an internal CAS signal ICAS, an internal read enable signal RDEN, an internal write enable signal WREN, etc. based on the control signals /CS, /RAS, /CAS, /WE and CKE from the memory controller 500 in FIG. 2. The internal RAS signal IRAS may be activated at a time point when the active command ACT is received, and the internal CAS signal ICAS may be activated at a time point when the read command RD or the write command WR is received. The internal read enable signal RDEN may be activated at a time point when the read command RD is received, and the internal write enable signal WREN may be activated at a time point when the write command WR is received.

The timing control logic 700 generates timing control signals based on the internal command signals IRAS, ICAS, RDEN and WREN. The timing control signals may include a precharge signal PCHB, a column selection enable signal CSEN, a discharge signal PDIS, a bias control signal PBSB, etc. as described below.

The address buffer 600 may generate a row address signal XADD and a column address signal YADD based on an external address ADD transferred from the memory controller 1100. The row address signal XADD may be provided to the row selection circuit 200 and the column address signal YADD may be provided to the column selection circuit 300.

The row selection circuit 200 may select a wordline corresponding to the row address signal XADD among the wordlines WL0 through WLn in response to the timing control signals from the timing control logic 700. The column selection circuit 300 may select a bitline corresponding to the column address signal YADD among the bitlines BL0 through BLm in response to the timing control signals from the timing control logic 700.

The write driver WDRV and the read sensing circuit RSEN are coupled to the bitlines BL0 through BLm. According to example embodiments, the write driver WDRV and the read sensing circuit RSEN may be coupled to the bitlines BL0 through BLm directly or via the column selection circuit 300.

According to example embodiments, the read sensing circuit RSEN may perform the precharge operation between the time point of receiving the active command ACT through the DRAM interface DIF and the time point of receiving the read command RD through the DRAM interface DIF, and senses the data stored in the resistive memory cells to provide the read data. In some example embodiments, the precharge operation may be performed in response to the precharge signal PCHB provided from the timing control logic 700.

The write driver WDRV may program the write data in the resistive memory cells. The write driver WDRV may be formed integrally with the read sensing circuit RSEN, or the write driver WDRV may be formed as a circuit distinct from the read sensing circuit RSEN

FIG. 7 is a circuit block diagram illustrating a resistive memory device according to an example embodiment.

FIG. 7 illustrates a resistive memory device 1200a including a local input-output circuit 400 that is commonly coupled to the bitlines BL0 through BLm via a single local line LIO. Some components in FIG. 6 are omitted in FIG. 7 for convenience of illustration.

Referring to FIG. 7, a memory cell array 100 includes a plurality of memory cells MC, which are disposed at the positions crossed by the wordlines WL0˜WLn and the bitlines BL0˜BLm.

Each memory cell MC may include a cell transistor CT and a resistive element CR. The cell transistor CT is turned on when the corresponding wordline is selected and enabled by the row selection circuit 200. The row selection circuit 200 may include a row decoder for decoding the row address signal XADD and a wordline driver circuit for applying a wordline selection voltage or a wordline non-selection voltage to the wordlines WL0˜WLn, respectively, in response to the outputs of the row decoder.

The cell transistor CT and the resistive element CR in each memory cell MC are coupled between a source line SL and one of the bitlines BL0˜BLm. Even though not illustrated in FIG. 7, a plurality of memory cells MCs may be coupled to the common source line. In some embodiments, the memory cell array 100 may be partitioned into at least two cell regions and the cell regions may be coupled to the different source lines.

The memory cell MC may be implemented with a phase-change random access memory (PRAM) cell using phase-change materials, a resistance random access memory (RRAM) cell using complex metal oxide of variable resistance, a ferroelectrics random access memory (FRAM) cell using ferroelectric materials and a magneto-resistive random access memory (MRAM) cell using ferromagnetic materials. In particular, the memory cell MC may be implemented with a spin-transfer torque magneto-resistive random access memory (STT-MRAM) cell. In this case, the resistive element CR may be implemented with a magnetic tunnel junction (MTJ) element of magnetic materials. Such resistive materials of the resistive element may have the resistance value depending on the magnitude and/or the direction of the applied current or voltage and have characteristics of non-volatility of maintaining the resistance value even though power is off.

The bitlines BL0˜BLm are coupled to a write driver WDRV. The write driver WDRV may be enabled in response to the reception of the write command WR and may perform a write operation by applying a current or voltage to the memory cell via the corresponding bitline. Even though FIG. 7 illustrates the write driver WDRV in the local input-output circuit 400, the write driver WDRV may include a plurality of driver units respectively coupled to the bitlines BL0˜BLm and the driver units may driver the bitlines BL0˜BLm simultaneously.

The column selection circuit 300 may include a column gating circuit 310 and a column decoder 350 for selecting the bitline corresponding to the column address signal YADD. The column decoder 350 generates column select signals CSL0˜CSLm to select one of the bitlines BL0˜BLm in response to the column address signal YADD and the column selection enable signal CSEN. The column selection enable signal CSEN may be provided from the timing control logic 700 in FIG. 6. The column gating circuit 310 may include a plurality of switches N0˜Nm coupled to the bitlines BL0˜BLm. The switches N0˜Nm are turned on selectively in response to the column select signals CSL0˜CSLm. The switch corresponding to the column address signal YADD is turned on to select the bitline and a data voltage or a data current related with the resistance value of the memory cell MC is transferred to the read sensing circuit 410 through the selected bitline.

The read sensing circuit 410 may be coupled to the bitlines BL0˜BLm via the column selection circuit 300. The read sensing circuit 410 senses the data stored in the memory cell MC to provide the read data. In general, a precharge operation with respect to the bitline is performed in an attempt to avoid a read disturbance and to secure a predetermined range of the bitline voltage. As described above, the read sensing circuit 410 may perform the precharge operation between the time point of receiving the active command ACT and the time point of receiving the read command RD. Such a hidden precharge operation may be performed in response to the precharge signal PCHB provided from the timing control logic 700.

FIG. 8 is a circuit diagram illustrating an example embodiment of a read sensing circuit in the resistive memory device of FIG. 7.

Referring to FIG. 8, the read sensing circuit 410 may include a local sensing node LSN, a precharge circuit 411, a bias circuit 412, a clamp circuit 413, a discharge circuit 414 and a sense amplifier 415.

The local sensing node LSN is electrically coupled to a selected bitline BLs corresponding to the column selection signal YADD, which is selected among the bitlines BL0˜BLm via the column selection circuit 300, as described above with reference to FIG. 7. The one column selection signal CSLs is activated in response to the column selection signal YADD among the column selection signals CSL0˜CSLm and the corresponding switch Ns is turned on to electrically couple the selected bitline BLs and the local sensing node LSN.

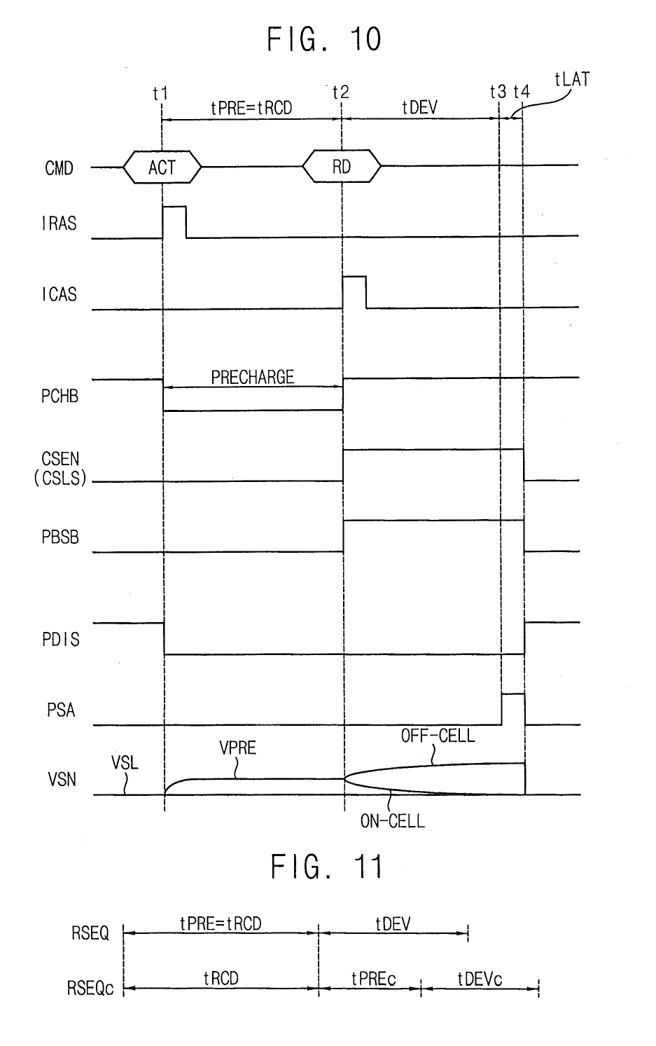

The precharge circuit 411 may precharge the local sensing node LSN with a precharge voltage VPRE in response to a precharge signal PCHB. The timing of the precharge signal PCHB is further described with response to FIGS. 9 and 10. After the selected bitline BLs is electrically coupled to the local sensing node LSN, the sense amplifier 415 may sense a voltage or a current on the local sensing node LSN to output the read data DO. The sense amplifier 415 may be enabled in response to a sensing enable signal PSA. The sense amplifier 415 may compare the sensed voltage or current with a reference signal REF to output the read data DO. The reference signal REF may be provided as a voltage signal or a current signal depending on the configuration of the sense amplifier 415. In other words, the reference signal REF may be a reference voltage or a reference current according to the sensing scheme of the read sensing circuit 410. The output read data DO corresponds to a resistance value programmed in a selected resistive memory cell MCs, which is coupled to the selected wordline WLs and the selected bitline BLs.

The bias circuit 412 may apply a bias voltage VPPSA to the local sensing node LSN in response to a bias control signal PBSB. The bias circuit 412 may apply a bias current to the local sensing node LSN at a time point when the selected bitline BLs is electrically coupled to the local sensing node LSN to enlarge the sensing margin. The clamp circuit 413 may be coupled between the selected bitline BLs and the local sensing node LSN. For example, the switch Ns and a read line RDL may be disposed between the selected bitline BLs and the clamp circuit 413. The clamp circuit 413 may prevent an excessive voltage from being applied to the selected memory cell MCs in response to a clamp voltage VCMP. When the clamp circuit 413 is omitted, the read line RDL may be the same node as the local sensing node LSN. The discharge circuit 414 may discharge the local sensing node LSN with a source voltage VSL in response to a discharge signal PDIS.

The sensing enable signal PSA, the discharge signal PDIS and the bias control signal PBSB may be provided from the timing control logic 700 in FIG. 6. The precharge circuit 411, the bias circuit 412, the claim circuit 413 and the discharge circuit 414 may includes switches such as the transistors as illustrated in FIG. 8. According to example embodiments, one or more of the bias circuit 412, the clamp circuit 413 and the discharge circuit 414 may be omitted.

FIG. 9 is a diagram illustrating a timing control circuit that generates a precharge signal according to an example embodiment.

The timing control circuit in FIG. 9 may be included in the timing control logic 700 in FIG. 6. The timing control circuit may include a precharge control circuit 511 and a column selection enable circuit 521.

The precharge control circuit 511 may generate a precharge signal PCHB in response to an internal RAS signal IRAS and an internal CAS signal ICAS. The precharge control circuit 511 may activate the precharge signal PCHB at a time point when the internal RAS signal IRAS is activated and then deactivate the precharge signal PCHB at a time point when the internal CAS signal ICAS is activated. As described with reference to FIG. 6, the internal RAS signal IRAS may be activated at the time point when the active command ACT is received from the memory controller and the internal CAS signal ICAS may be activated at the time point when the read command RD is received from the memory controller. As a result, the precharge control circuit 511 may generate the precharge signal PCHB that is activated in response to the active command ACT and deactivated in response to the read command RD.

The column selection enable circuit 521 may generate a column selection enable signal CSEN in response to the internal CAS signal ICAS. The column selection enable circuit 521 may activate the column selection enable signal CSEN at a time point when the internal CAS signal ICAS is activated. As a result, the column selection enable signal CSEN may be activated at the time point when the precharge signal PCHB is deactivated in response to the internal CAS signal ICAS. In other words, the selected bitline BLs may be electrically coupled to the local sensing node LSN in response to the column selection enable signal CSEN simultaneously with the end of the precharge operation.

FIG. 10 is a timing diagram illustrating an operation of a resistive memory device according to an example embodiment.

Referring to FIGS. 6 through 10, until a time point t1 when the read operation begins, the sensing node voltage VSN may maintain the source voltage VSL that is initialized in response to the discharge signal PDIS by the discharge circuit 414.

At the time point t1 when the resistive memory device 1200a receives the active command ACT, the command decoder 500 may activate the internal RAS signal IRAS. The precharge control circuit 511 activates the precharge signal PCHB in the logic low level in response to the internal RAS signal IRAS. The precharge circuit 411 may apply the precharge voltage VPRE to the local sensing node LSN in response to the precharge signal PCHB and the sensing node voltage VSN is precharged to the precharge voltage VPRE. The discharge circuit 414 may be disabled in response to the discharge signal PDIS that is deactivated in the logic low level.

At a time point t2 when the resistive memory device 1200a receives the read command RD after the RAS-to-CAS delay time tRCD, the command decoder 500 may activate the internal CAS signal ICAS. The precharge control circuit 511 may deactivate the precharge signal PCHB in the logic high level in response to the internal CAS signal ICAS. The precharge circuit 411 may be disabled in response to the precharge signal PCHB being deactivated. As a result, the precharge time tPRE may be substantially the same as the RAS-to-CAS delay time tRCD.

At the time point t2, the column selection enable circuit 521 may activate the column selection enable signal CSEN in the logic high level in response to the internal CAS signal ICAS. Thus the local sensing node LSN may be electrically coupled to the selected bitline BLs in response to the activated column selection signal CSLs. At the same time, the bias circuit 412 may be enabled to apply the bias current to the local sensing node LSN. The sensing node voltage VSN is developed according to the resistance value of the selected memory cell MCs. The sensing node voltage VSN may increase higher than the precharge voltage VPRE when the selected memory cell MCs is an off-cell having relatively the higher resistance value, whereas the sensing node voltage VSN may decrease lower than the precharge voltage VPRE when the selected memory cell MCs is an on-cell having relatively the lower resistance value.

At a time point t3 after the develop time tDEV, the sensing enable signal PSA is enabled and then the sense amplifier 415 compares the developed sensing node voltage VSN with the reference voltage REF to latch and output the read data DO. If the sense amplifier 415 has a configuration for current sensing, the sense amplifier 415 may compare a current through the local sensing node LSN with the reference current REF to latch and output the read data DO.

At a time point t4 after the latch time tLAT, the column selection enable signal CSEN and the bias control signal PBSB are deactivated in the logic low level and the discharge signal PDIS is activated in the logic high level to reset the read sensing circuit 410 to the initial state.

As such, the resistive memory device 1200a may perform a hidden precharge operation using the precharge signal PCHB, which is activated (e.g., in the logic low level) during the RAS-to-CAS delay time tRCD between the time point t1 when the active command ACT is received and the time point t2 when the read command RD is received.

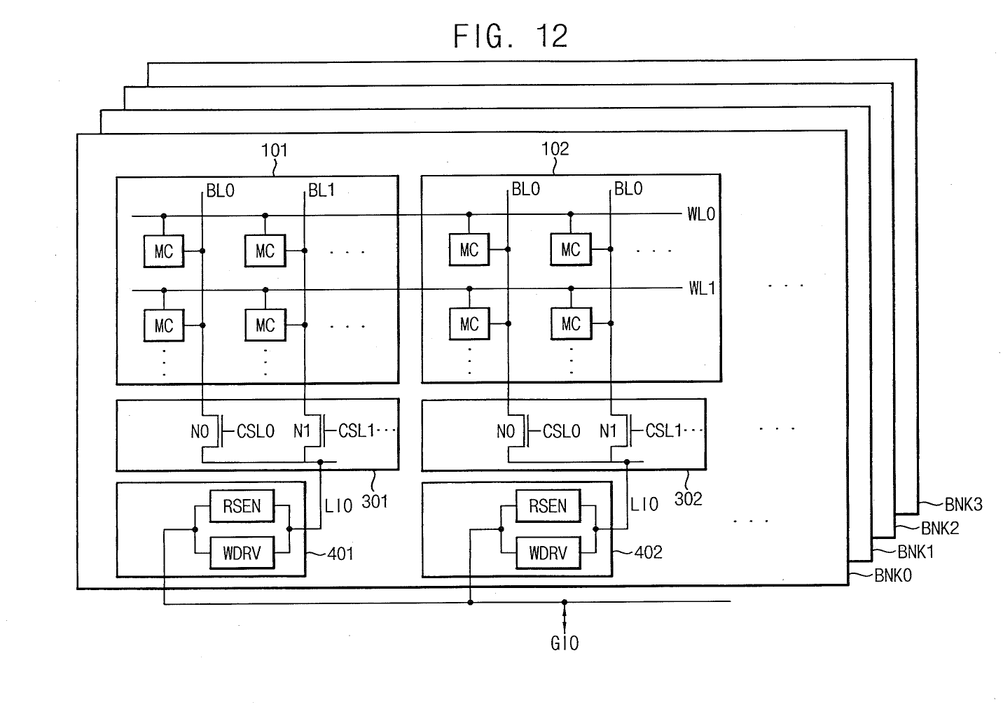

FIG. 11 is a diagram for describing a read sequence in a method of reading data according to example embodiments.

As illustrated in FIG. 11, a read sequence RSEQ using the hidden precharge according to example embodiments requires a total time of the RAS-to-CAS delay time tRCD and the develop time tDEV, whereas the conventional read sequence RSEQc requires a total time of the RAS-to-CAS delay time tRCD, the precharge time tPREc and the develop time tDEV.

The precharge time tPRE may be overlapped in the RAS-to-CAS delay time tRCD according to example embodiments, and thus the time for the read sequence RSEQ may be reduce compared with the conventional read sequence RSEQc. As the time for the read sequence RSEQ is reduced, the develop time tDEV may be further increased to secure the sufficient sensing margin and enhance the reliability of the read data DO.

FIG. 12 is a block diagram illustrating a resistive memory device including a plurality of memory banks according to an example embodiment.

As illustrated in FIG. 12, the resistive memory device may include a plurality of memory banks BNK0˜BNK3. FIG. 12 illustrates the four memory banks BNK0˜BNK3 for convenience of illustration, the number of memory banks may be determined variously. The memory bank may represent a group of memory cells, which operate independently of memory cells in other memory banks for the high operational speed of the memory device. The memory cells in the same memory bank may share the data bus and/or the address-control signal lines. The memory bank may include one or more memory blocks.

Referring to FIG. 12, each memory bank may include a plurality of memory blocks 101 and 102. In this case, the memory bank may include a plurality of column gating circuits 301 and 302 and a plurality of local input-output circuits 401 and 402 corresponding to the respective memory blocks 101 and 102. Each of the column gating circuits 301 and 302 may include switches N0 and N1 that are selectively turned on in response to the column selection signals CSL0 and CSL1. The local input-output circuits 401 and 402 may be coupled to the memory blocks 101 and 102 via the local input-output lines LIOs. The local input-output circuits 401 and 402 may exchange the read and write data with the memory controller 1100 in FIG. 2 via the global input-output line GIO. Each of the local input-output circuits 401 and 402 may include a read sensing circuit RSEN and a write driver WDRV. As described above, the read sensing circuit RSEN may be configure to perform a read operation with a hidden precharge operation.

Even though not illustrated in FIG. 12, the row selection circuits and the column decoders may be disposed near the respective memory banks. Based on the above-mentioned bank address BA, at least one memory bank may be selected among the memory banks BNK0˜BNK3 for the read operation or the write operation.

FIG. 13 is a diagram illustrating an example of a resistive memory cell in a memory cell array.

Referring to FIG. 13, a memory cell may include a resistive element RE1 and a diode D1 serially coupled between a bitline BL and a wordline WL. The memory cell of FIG. 13 may determine a resistance distribution of the resistive element RE1 by controlling voltages applied to the bitline BL and the wordline WL. The configuration of the memory cell of FIG. 13 may be adopted when the resistive element RE1 is a unipolar type. The write operation may be performed by applying the voltages to the bitline BL and the wordline WL, thereby controlling a voltage difference between both ends of the resistive element RE1 or controlling a current flowing through the resistive element RE1.

FIG. 14 is a diagram illustrating another example of a resistive memory cell in a memory cell array.

Referring to FIG. 14, a memory cell may include a resistive element RE2 and a switching element, such as a cell transistor CT1, serially coupled between a bitline BL and a source line SL. A gate of the cell transistor CT1 is coupled to a wordline WL. The memory cell of FIG. 14 may determine a resistance distribution of the resistive element RE2 by controlling voltages applied to the bitline BL and the common source line CSL. The configuration of the memory cell of FIG. 14 may be adopted when the resistive element RE2 is a bipolar type as well as a unipolar type.

When the resistive element RE2 is a unipolar type, a resistance value of the resistive element RE2 is controlled by magnitude of applied voltage. When the resistive element RE2 is a bipolar type, the resistance value of the resistive element RE2 may be controlled by direction (i.e. polarity) of the applied voltage as well as magnitude of the applied voltage. The write operation may be performed by applying the voltages to the bitline BL and the source line SL, thereby controlling a voltage difference between both ends of the resistive element RE2 or controlling a current flowing through the resistive element RE2.

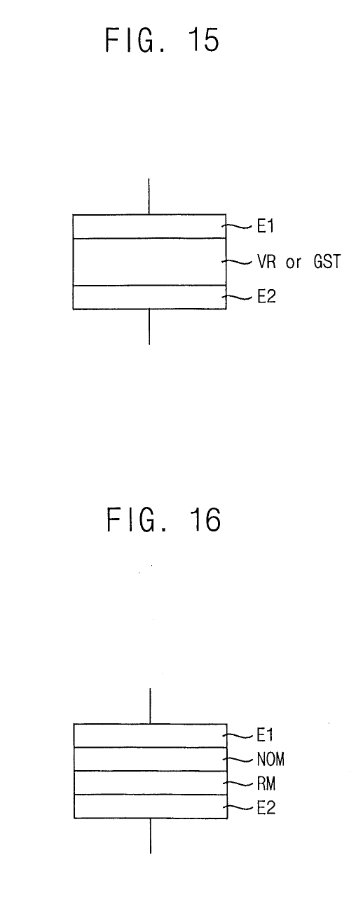

FIG. 15 a diagram illustrating an example of a unipolar resistive element in the resistive memory cell of FIGS. 13 and 14.

Referring to FIG. 15, the resistive element RE1 of FIG. 13 or the resistive element RE2 of FIG. 14 may include a first electrode E1, a second electrode E2 and resistive material between the electrodes E1 and E2. The electrodes E1 and E2 may be formed with metal such as tantalum (Ta), platinum (Pt), etc. The resistive material may include transition-metal oxide (VR) such as cobalt oxide, or phase change material such as GeSbTe (GST), etc. The phase change material may be in amorphous state or in crystalline state depending on heating time and/or heating temperature, and thus the phase change material may change its resistance according to phase change.

PRAM using phase change materials, RRAM using materials having variable resistance, and MRAM using ferromagnetism materials may be differentiated from each other, and those may be totally referred to as resistive memories. Method and devices according to example embodiments may be applied to various resistive memories including PRAM, RRAM and MRAM.

The resistive material between the electrodes E1 and E2 is required to have a plurality of stable states having different resistance, and various resistive materials are being studied.

For example, while increasing a voltage applied to material having characteristic of Negative Differential Resistance (NDR), resistance of the NDR material abruptly increases at a reset voltage (Vreset), the relatively high resistance is maintained afterwards, and then the NDR material transitions to a state of relatively low resistance at a set voltage (Vset). In this case, the set voltage (Vset) for decreasing the resistance of the NDR material is greater than the reset voltage (Vreset) for decreasing the resistance of the NDR material.

Chalcogenide using telluride compound such as GeSbTe has relatively high resistance when relatively low voltage is applied, and transitions to a state of relatively low resistance if a sufficiently high voltage is applied. In this case, the set voltage (Vset) for decreasing the resistance of the Chalcogenide is smaller than the reset voltage (Vreset) for decreasing the resistance of the Chalcogenide.

As such, an on-state of relatively low resistance and an off-state of relatively high resistance may be programmed or written into memory cells by applying the set voltage (Vset) and the reset voltage (Vreset) corresponding to characteristics of various materials included in the memory cells.

FIG. 16 a diagram illustrating an example of a bipolar resistive element in the resistive memory cell of FIG. 14.

Referring to FIG. 16, the resistive element RE2 of FIG. 14 may include a first electrode E1, a second electrode E2, non-ohmic material (NOM) and resistive material (RM) between the electrodes E1 and E2. In this case, the on-state and the off-state may be programmed or written into memory cells by applying opposite voltages to the electrodes E1 and E2. In other words, the on-state and the off-state may be determined according to polarity of the applied voltage.

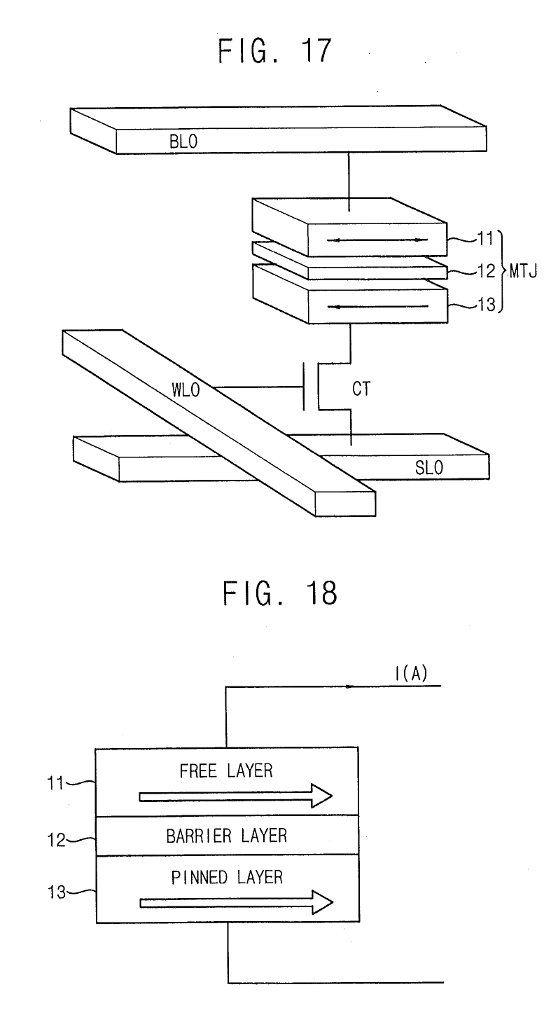

FIG. 17 is a diagram illustrating an example of a spin-transfer torque magneto-resistive random access memory (STT-MRAM) cell in the memory cell array of FIG. 6.

Referring to FIG. 17, the STT-MRAM cell may include an MTJ element and a cell transistor CT. A gate of the cell transistor CT is coupled to a corresponding wordline WL0, a first electrode of the cell transistor CT is coupled to a corresponding bitline BL0 via the MTJ element, and a second electrode of the cell transistor CT is coupled to a source line SL0.

The MTJ element may include a pinned layer 13, a free layer 11 and a barrier layer 12 between the two layers 11 and 13. The magnetization direction of the pinned layer 13 is fixed but the magnetization direction of the free layer 11 may be varied, according to the written data, between the same direction as or opposite direction to the magnetization direction of the pinned layer 13. In one example embodiment, an anti-ferromagnetic layer may be further included in the MTJ element to enforce the magnetization direction of the pinned layer 13.

For example, to perform the write operation of the STT-MRAM cell, a high level voltage is applied to the wordline WL0 to turn on the cell transistor CT, and a write current WC1 or WC2 as illustrated in FIG. 20 is applied between the bitline BL0 and the source line SL0.

For example, to perform the read operation of the STT-MRAM cell, a high level voltage is applied to the wordline WL0 to turn on the cell transistor CT, a read current is applied to flow from the bitline BL0 to the source line SL0, and the resistance value is measured to determine the data stored in the MTJ element.

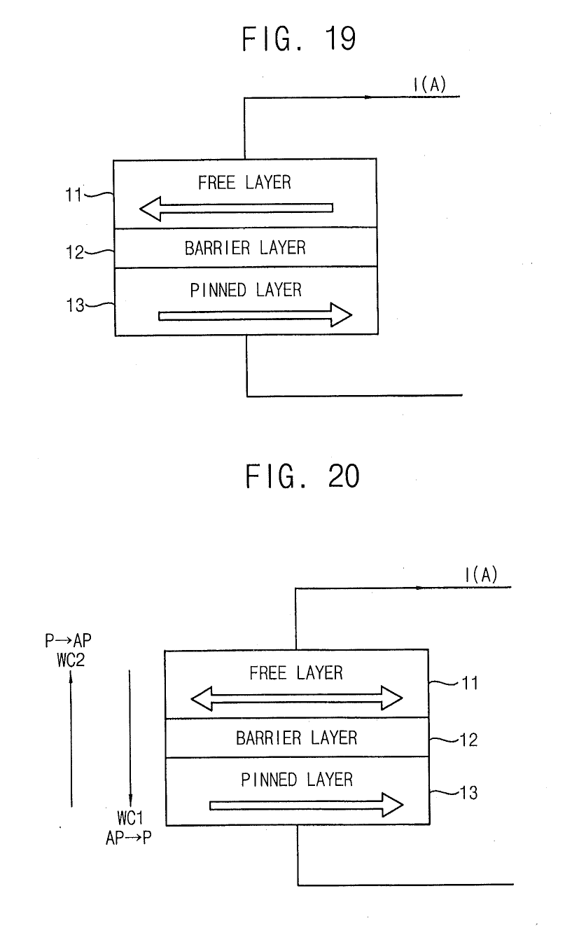

FIGS. 18 and 19 are diagrams illustrating magnetization directions of a magnetic tunnel junction (MTJ) element depending on written data.

The resistance value of the MTJ element may be changed according to the magnetization direction of the free layer 11. When the read current I(A) is applied to the MTJ element, the data voltage depending on the resistance value of the MTJ element is output. The magnitude of the read current I(A) is much smaller than the magnitude of a write current and thus the magnetization direction of the free layer is not changed due to the read current I(A).

Referring to FIG. 18, the magnetization direction of the free layer 11 may be arranged parallel with the magnetization direction of the pinned layer 13. In this case, the MTJ element has a relatively smaller resistance value and the data ‘0’ may be read out by applying the read current I(A).

Referring to FIG. 19, the magnetization direction of the free layer 11 may be arranged opposite to the magnetization direction of the pinned layer 13. In this case, the MTJ element has a relatively greater resistance value and the data ‘1’ may be read out by applying the read current I(A).

FIG. 20 is a diagram for describing a write operation of the STT-MRAM cell.

Referring to FIG. 20, the magnetization direction of the free layer 11 may be determined depending on the write currents WC1 and WC2. For example, when the first write current WC1 is applied to the MTJ element, the free electrons having the same spin direction as the pinned layer 13 apply a torque to the free layer 11 and thus the free layer 11 is magnetized in the same direction as, that is, parallel direction (P) with the pinned layer 13. When the second write current WC2 is applied to the MTJ element, the free electrons having the opposite spin direction to the pinned layer 13 apply a torque to the free layer 11 and thus the free layer 11 is magnetized in the opposite direction as, that is, anti-parallel direction (AP) with the pinned layer 13. As such the magnetization direction of the free layer 11 in the MTJ element may be changed by the spin transfer torque (STT).

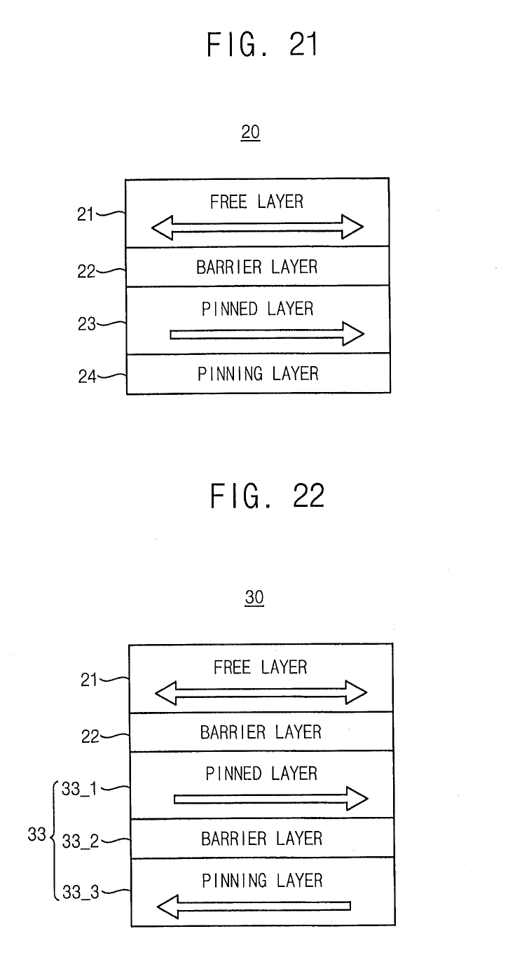

FIGS. 21 through 25 are diagrams illustrating examples of the MTJ element in the STT-MRAM cell.

FIGS. 21 and 22 illustrate examples of the MTJ element having the horizontal magnetization, corresponding to a case that the direction of an applied current is perpendicular to the easy-magnetization axis.

Referring to FIG. 21, an MTJ element 20 may include a free layer 21, a barrier layer 22, a pinned layer 23 and a pinning layer 24.

The free layer 21 may include materials having a variable magnetization direction. The magnetization direction of the free layer 21 may be varied depending on internal and/or external electrical and/or magnetic factors. The free layer 21 may be implemented with ferromagnetic materials including at least one of cobalt (Co), iron (Fe) and nickel (Ni). For example, the free layer 21 may include at least one of FeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO and Y3Fe5O12.

The barrier layer 22 may have a width shorter than a spin diffusion distance. The barrier layer 22 may be implemented with non-magnetic materials. For example, the barrier layer 22 may include at least one of Mg, Ti, Al, an oxide of MgZn or MgB, and a nitride of Ti or V.

The pinned layer 23 may have the magnetization direction that is fixed by the pinning layer 24. The pinned layer 23 may be implemented with ferromagnetic materials. For example, the pinned layer 23 may include at least one of FeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO and Y3Fe5O12.

The pinning layer 24 may be implemented with anti-ferromagnetic materials. For example, the pinning layer 24 may include at least one of PtMn, IrMn, MnO, MnS, MnTe, MnF2, FeCl2, FeO, CoCl2, CoO, NiCl2, NiO and Cr.

When the free layer and the pinned layer are implemented with ferromagnetic materials, a stray field may be generated in edge portions of the ferromagnetic materials. The stray field may decrease magneto-resistance or increase the resistive magnetism in the free layer, thereby causing asymmetric switching. Thus the MTJ element may require structure for reducing or controlling the stray field due to the ferromagnetic materials.

Referring to FIG. 22, a fixed layer 33 in an MTJ element 30 may be implemented with synthetic anti-ferromagnetic (SAF). The fixed layer 33 may include a pinned layer 33_1, a barrier layer 33_2 and a pinning layer 33_3. Each of the pinned layer 33_1 and the pinning layer 33_3 may include at least one of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO and Y3Fe5O12. The magnetization directions of the pinned layer 33_1 and the pinning layer 33_3 may be different from each other and the magnetization directions of the pinned layer 33_1 and the pinning layer 33_3 may be fixed, respectively. The barrier layer 33_2 may include Ru.

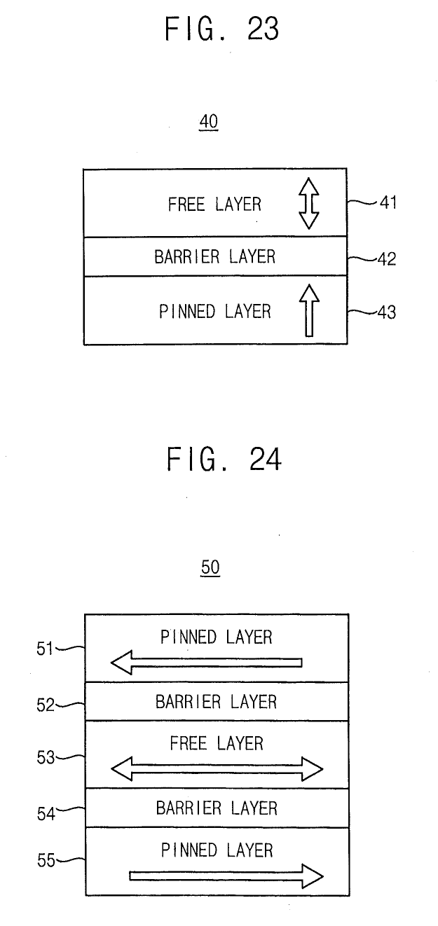

FIG. 23 illustrates an example of the MTJ element having the vertical magnetization, corresponds to a case that the direction of an applied current is parallel with the easy-magnetization axis.

Referring to FIG. 23, an MTJ element 40 includes a free layer 41, a barrier layer 42 and a pinned layer 43. The MTJ element 40 has a relatively smaller resistance when the magnetization direction of the free layer 41 is parallel with the magnetization direction of the pinned layer 43, and the MTJ element 40 has a relatively greater resistance when the magnetization direction of the free layer 41 is opposite to the magnetization direction of the pinned layer 43. The data may be stored as the resistance value.

For example, to implement the MTJ element 40 having the vertical magnetization, the free layer 41 and the pinned layer 43 may be implemented with materials having higher magnetic anisotropic energy such as alloys of amorphous rare-earth elements, multilayer thin films as (Co/Pt)n and (Fe/Pt)n, superlattice materials of L10 crystalline structure. The free layer 41 may be an ordered alloy including at least one of Fe, Co, Ni, Pa and Pt. For example, the free layer 41 may include at least one of Fe—Pt alloy, Fe—Pd alloy, Co—Pd alloy, Co—Pt alloy, Fe—Ni—Pt alloy, Co—Fe—Pt alloy, and Co—Ni—Pt alloy. Such alloys may be, quantochemically, Fe50Pt50, Fe50Pd50, Co50Pd50, Co50Pt50, Fe30Ni20Pt50, Co30Fe20Pt50, or Co30Ni20Pt50.

The pinned layer 43 may be an ordered alloy including at least one of Fe, Co, Ni, Pa and Pt. For example, the pinned layer 43 may include at least one of Fe—Pt alloy, Fe—Pd alloy, Co—Pd alloy, Co—Pt alloy, Fe—Ni—Pt alloy, Co—Fe—Pt alloy, and Co—Ni—Pt alloy. Such alloys may be, quantochemically, Fe50Pt50, Fe50Pd50, Co50Pd50, Co50Pt50, Fe30Ni20Pt50, Co30Fe20Pt50, or Co30Ni20Pt50.

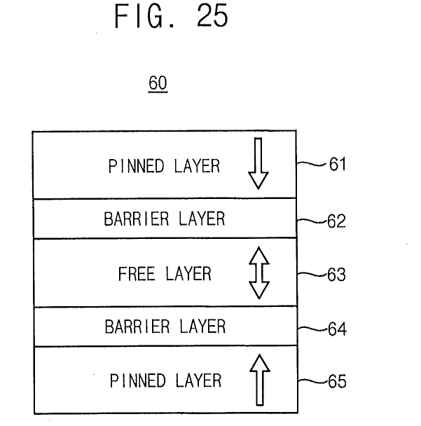

FIGS. 24 and 25 illustrate examples of a dual MTJ element having a structure that two pinned layers and two barrier layers are centered on a free layer.

Referring to FIG. 24, a dual MTJ element 50 forming horizontal magnetization may include a first barrier layer 51, a first barrier layer 52, a free layer 53, a second barrier layer 54 and a second pinned layer 55. The materials forming the respective layers may be the same as or similar to the materials of the free layer 21, the barrier layer 22 and the pinned layer 23 in FIG. 21.

In one example embodiment, when the magnetization direction of the first pinned layer 51 is fixed in the opposite direction to the magnetization direction of the second pinned layer 55, the magnetic fields due to the first and second pinned layers 51 and 55 may be interfered destructively. Accordingly, data may be written in the dual MTJ element 50 using the smaller write current than the single MTJ element. Also the exact data may be read from the dual MTJ element 50 because the MTJ element 50 provides the greater resistance value due to the second barrier layer 54.

Referring to FIG. 25, a dual MTJ element 60 forming vertical magnetization may include a first barrier layer 61, a first barrier layer 62, a free layer 63, a second barrier layer 64 and a second pinned layer 65. The materials forming the respective layers may be the same as or similar to the materials of the free layer 41, the barrier layer 42 and the pinned layer 43 in FIG. 8.

In one example embodiment, when the magnetization direction of the first pinned layer 61 is fixed in the opposite direction to the magnetization direction of the second pinned layer 65, the magnetic fields due to the first and second pinned layers 61 and 65 may be interfered destructively. Accordingly, data may be written in the dual MTJ element 60 using the smaller write current than the single MTJ element.

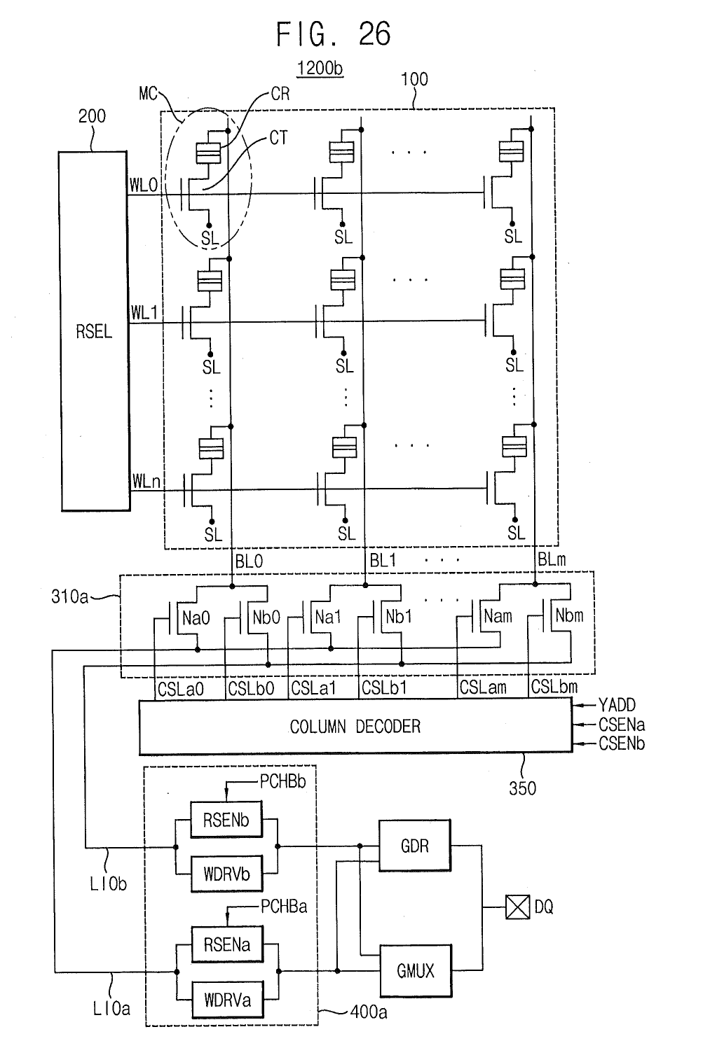

FIG. 26 is a circuit diagram illustrating a resistive memory device according to an example embodiment.

FIG. 26 illustrates a resistive memory device 1200b including a local input-output circuit 400a that is commonly coupled to the bitlines BL0 through BLm via two local lines LIOa and LIOb. Some components in FIG. 6 are omitted in FIG. 26 for convenience of illustration.

Referring to FIG. 26, a memory cell array 100 includes a plurality of memory cells MC, which are disposed at the positions crossed by the wordlines WL0˜WLn and the bitlines BL0˜BLm.

Each memory cell MC may include a cell transistor CT and a resistive element CR. Even though a bipolar type of FIG. 14 is illustrated, the unipolar type of FIG. 13 may be included in the memory cell array 100. The cell transistor CT and the resistive element CR in each memory cell MC are coupled between a source line SL and one of the bitlines BL0˜BLm. Even though not illustrated in FIG. 26, a plurality of memory cells MCs may be coupled to the common source line. In some embodiments, the memory cell array 100 may be partitioned to at least two cell regions and the cell regions may be coupled to the different source lines.

The cell transistor CT is turned on when the corresponding wordline is selected and enabled by the row selection circuit 200. The row selection circuit 200 may include a row decoder for decoding the row address signal XADD and a wordline driver circuit for applying a wordline selection voltage or a wordline non-selection voltage to the wordlines WL0˜WLn, respectively, in response to the outputs of the row decoder.

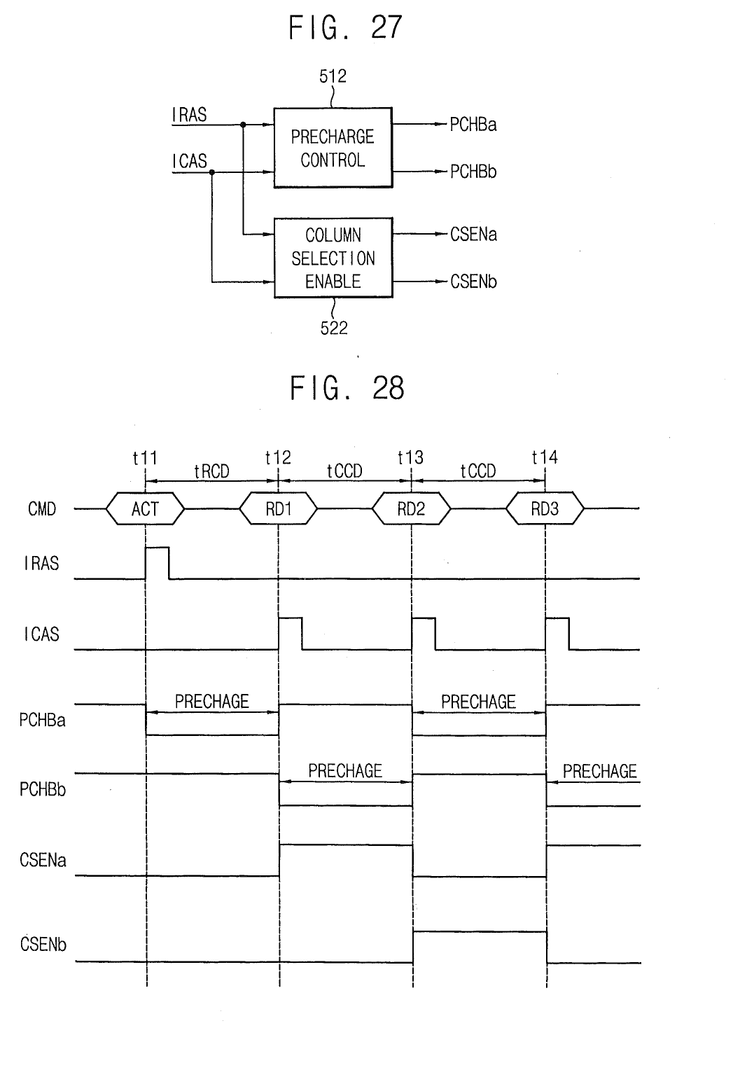

The column selection circuit 300 may include a column gating circuit 310a and a column decoder 350 for selecting the bitline corresponding to the column address signal YADD. The column decoder 350 generates first column select signals CSLa0˜CSLam in response to the column address signal YADD and the first column selection enable signal CSENa, and generates second column select signals CSLb0˜CSLbm in response to the column address signal YADD and the second column selection enable signal CSENb. The first column select signals CSLa0˜CSLam and the second column select signals CSLb0˜CSLbm may be provided from the timing control logic 700 in FIG. 6, and may be activated complementarily as described with reference to FIGS. 27 and 28. The column gating circuit 310a may include a plurality of first switches Na0˜Nam selectively turned on in response to the first column select signals CSLa0˜CSLam and a plurality of second switches Nb0˜Nbm selectively turned on in response to the second column select signals CSLb0˜CSLbm. The one switch corresponding to the column address signal YADD is turned on among the switches Na0˜NaM and Nb0˜Nbm to select the bitline and a data voltage or a data current related with the resistance value of the memory cell MC is transferred to the local input-output circuit 400a through the selected bitline.

One of first and second read sensing circuits RSENa and RSENb may be selected in response to the first and second column selection enable signals CSENa and CSENb, which are activated complementarily, and the selected one read sensing circuit may be electrically coupled to the selected bitline corresponding to the column address YADD.

The local input-output circuit 400a may include the first write driver WDRVa, the first read sensing circuit RSENa, which are coupled to the first local line LIOa, the second write driver WDRVb and the second read sensing circuit RSENb, which are coupled to the second local line LIOb. One of the first and second read sensing circuits RSENa and RSENb may be selectively coupled to the bitlines BL0˜BLm via the column gating circuit 310a and the selected one may sense the data stored in the memory cell MC to provide the read data. The first read sensing circuit RSENa may perform the precharge operation in response to the first precharge signal PCHBa and the second read sensing circuit RSENb may perform the precharge operation in response to the second precharge signal PCHBb. The first and second read sensing circuits RSENa and RSENb may be the same as described with reference to FIG. 8, except that the first and second read sensing circuits RSENa and RSENb precharge the respective local sensing nodes selectively in response to the first and second precharge signals PCHBa and PCHBb, which are activated complementarily.

The local input-output circuit 400a may be coupled to the data pin DQ via the global driver GDR and the global multiplexer GMUX, and exchange data with the memory controller via the data pin DQ.

FIG. 27 is a diagram illustrating a timing control circuit that generates a precharge signal according to an example embodiment.

The timing control circuit in FIG. 27 may be included in the timing control logic 700 in FIG. 6. The timing control circuit may include a precharge control circuit 512 and a column selection enable circuit 522.

The precharge control circuit 512 may generate a first precharge signal PCHBa and the second precharge signal PCHBb in response to an internal RAS signal IRAS and an internal CAS signal ICAS. As described with reference to FIG. 6, the internal RAS signal IRAS may be activated at the time point when the active command ACT is received from the memory controller and the internal CAS signal ICAS may be activated at the time point when the read command RD is received from the memory controller. As illustrated in FIG. 28, the first precharge signal PCHBa may be activated in response to the active command ACT and deactivated in response to a first read command RD 1 and then the first precharge signal PCHBa may be repeatedly activated and deactivated in response to other read commands RD2 and RD3 that are sequentially received after the first read command RD1. The second precharge signal PCHBb may be activated and deactivated complementarily with the first precharge signal PCHBa.

The column selection enable circuit 522 may generate a first column selection enable signal CSENa and a second column selection enable signal CSENb in response to the internal CAS signal ICAS. The first column selection enable signal CSENa and the second column selection enable signal CSENb may be activated complementarily as illustrated in FIG. 28.

FIG. 28 is a timing diagram illustrating an operation of a resistive memory device according to an example embodiment.

Referring FIGS. 6, 26, 27 and 28, the command decoder 500 may activate the internal RAS signal IRAS at a time point t11 when the active command ACT is received, and activate the internal CAS signal ICAS at time points t12, t13 and t14 when the read commands RD1, RD2 and RD3 are received.

At the time point t11 when the resistive memory device 1200b receives the active command ACT, the precharge control circuit 512 activates the first precharge signal PCHBa in the logic low level in response to the internal RAS signal IRAS. The first read sensing circuit RSENa begins the precharge operation in response to the activation of the first precharge signal PCHBa with respect to a first local sensing node coupled to the first local line LIOa.

At the time point t12 when the resistive memory device 1200b receives the first read command RD1, the precharge control circuit 512 deactivates the first precharge signal PCHBa in the logic high level and activates the second precharge signal PCHBb in the logic low level in response to the internal CAS signal ICAS. The first read sensing circuit RSENa quits the precharge operation in response to the deactivation of the first precharge signal PCHBa, and the second read sensing circuit RSENb begins the precharge operation in response to the activation of the second precharge signal PCHBb with respect to a second local sensing node coupled to the second local line LIOb.

In addition, at the time point t12, the column selection enable circuit 522 activates the first column selection enable signal CSENa in the logic high level in response to the internal CAS signal ICAS. In response to the activation of the first column selection enable signal CSENa, the selected bitline is electrically coupled to the first local line LIOa and the first read sensing circuit RSENa begins the develop operation as described with reference to FIG. 10.

At the time point t13 when the resistive memory device 1200b receives the second read command RD2, the precharge control circuit 512 activates the first precharge signal PCHBa in the logic low level and deactivates the second precharge signal PCHBb in the logic high level in response to the internal CAS signal ICAS. The first read sensing circuit RSENa begins the precharge operation in response to the activation of the first precharge signal PCHBa, and the second read sensing circuit RSENb quits the precharge operation in response to the deactivation of the second precharge signal PCHBb.

In addition, at the time point t13, the column selection enable circuit 522 deactivates the first column selection enable signal CSENa in the logic low level and activates the second column selection enable signal CSENb in the logic high level, in response to the internal CAS signal ICAS. The previously selected bitline is disconnected from the first local line LIOa in response to the deactivation of the first column selection enable signal CSENa, and a newly selected bitline is electrically coupled to the second local line LIOb in response to the activation of the second column selection enable signal CSENb. As such the first read sensing circuit RSENa begins the precharge operation again, and the second read sensing circuit RSENb begins the develop operation.

At the time point t14 when the resistive memory device 1200b receives the third read command RD3, the precharge control circuit 512 deactivates the first precharge signal PCHBa in the logic high level and activates the second precharge signal PCHBb in the logic low level in response to the internal CAS signal ICAS. The first read sensing circuit RSENa quits the precharge operation in response to the deactivation of the first precharge signal PCHBa, and the second read sensing circuit RSENb begins the precharge operation in response to the activation of the second precharge signal PCHBb.

In addition, at the time point t14, the column selection enable circuit 522 activates the first column selection enable signal CSENa in the logic high level and deactivates the second column selection enable signal CSENb in the logic low level, in response to the internal CAS signal ICAS. The previously selected bitline is disconnected from the second local line LIOb in response to the deactivation of the second column selection enable signal CSENb, and a newly selected bitline is electrically coupled to the first local line LIOa in response to the activation of the first column selection enable signal CSENa. As such the first read sensing circuit RSENa quits the precharge operation, and the second read sensing circuit RSENb begins the develop operation.

As a result, the second read sensing circuit RSENb may perform the precharge operation while the first read sensing circuit RSENa performs the develop operation and the latch operation during the time interval t12 to t13. On the contrary, the first read sensing circuit RSENa may perform the precharge operation while the second read sensing circuit RSENb performs the develop operation and the latch operation during the time interval t13 to t14.

As such, alternative sensing operations may be performed using the two read sensing circuits RSENa and RSENb with the complementarily-activated precharge signals PCHBa and PCHBb and the complementarily-activated column selection enable signals CSENa and CSENb. Through the alternative sensing operations, the CAS-to-CAS delay time tCCD may be reduced and the performance of the resistive memory device may be enhanced.

FIG. 29 is a circuit diagram illustrating a resistive memory device according to an example embodiment.

FIG. 29 illustrates a resistive memory device 1200c including a read sensing circuit 430 that is directly coupled to the bitlines BL0 through BLm. Some components in FIG. 6 are omitted in FIG. 29 for convenience of illustration. The memory cell array 100, the row selection circuit 200 and the column gating circuit 310 in FIG. 29 are the same as those in FIG. 7 and thus the repeated descriptions are omitted.

Referring to FIG. 29, the read sensing circuit 430 may include a plurality of bitline sensing units BLSAs respectively coupled to the bitlines BL0˜BLm. The bitline sensing units BLSAs may perform a page open operation such that the bitline sensing units BLSAs sense and latch simultaneously a plurality of data bits that are stored in the resistive memory cells commonly coupled to a selected wordline WLs, where the selected wordline WLs is selected among the wordlines WL0˜WLn in response to the row address XADD. The bit number opened simultaneously may be determined by the number of memory cells coupled to the one wordline and the number of the memory banks that are simultaneously selected.

According to the example embodiments, the read sensing circuit 430 may perform the precharge operation between the time point when the active command ACT is received and the time point when the read command RD is received. Such hidden precharge operation may be performed in response to the precharge signal PCHB provided from the timing control logic 700 in FIG. 6.

In the configuration of FIG. 29, switches N0˜Nm in the column gating circuit 310 are irrelevant with the electrical connection between the bitline and the sensing node. The switches N0˜Nm may control the output timing of the data bits in response to the column selection signals CSL0˜CSLm, where the data bits are latched in the bitline sensing units BLSAs during the page open operation and then transferred sequentially to the local multiplexer LMUX in response to the column selection signals CSL0˜CSLm that are sequentially activated.

FIG. 30 is a circuit diagram illustrating an example embodiment of a read sensing circuit in the resistive memory device of FIG. 29.

Referring to FIG. 30, the read sensing circuit 430 may include a plurality of bitline sensing units BLSAs, which have the same configuration and operational timing. Each bitline sensing unit BLSA may include a bitline sensing node BSN, a develop switch TD, a precharge circuit and a sense amplifier. As illustrated in FIG. 30, the precharge circuit may be implemented with one precharge transistor TP.

The develop switch may electrically couple the corresponding bitline BLi (i=1˜m) to the bitline sensing node BSN in response to a develop control signal DEVC. The precharge circuit TP may precharge the bitline sensing node BSN in response to the precharge signal PCHB. The sense amplifier configured to, after the selected bitline is electrically coupled to the bitline sensing node, sense a voltage or a current on the bitline sensing node to latch a bit of the read data. After the corresponding bitline BLi is coupled to the bitline sensing node BSN, the sense amplifier SA senses a voltage or a current on the bitline sensing node BSN to latch the read data. The sense amplifier may compare the voltage or the current on the bitline sensing node BSN with a reference signal REF to latch the read data.

As such, using the plurality of bitline sensing units BLSAs respectively coupled to the bitlines BL0˜BLm, the page open operation may be performed to simultaneously sense and latch data bits stored in a plurality of memory cells.

In addition, as described above, the read sensing circuit 430 may perform the hidden precharge operation during the RAS-to-CAS delay time tRCD. The bitline sensing units BLSAs in the read sensing circuit 430 may be controlled by the common precharge signal PCHB, and thus the hidden precharge operation may be performed with respect to the bitline sensing nodes BSNs, which are included respectively in the bitline sensing units BLSAs.

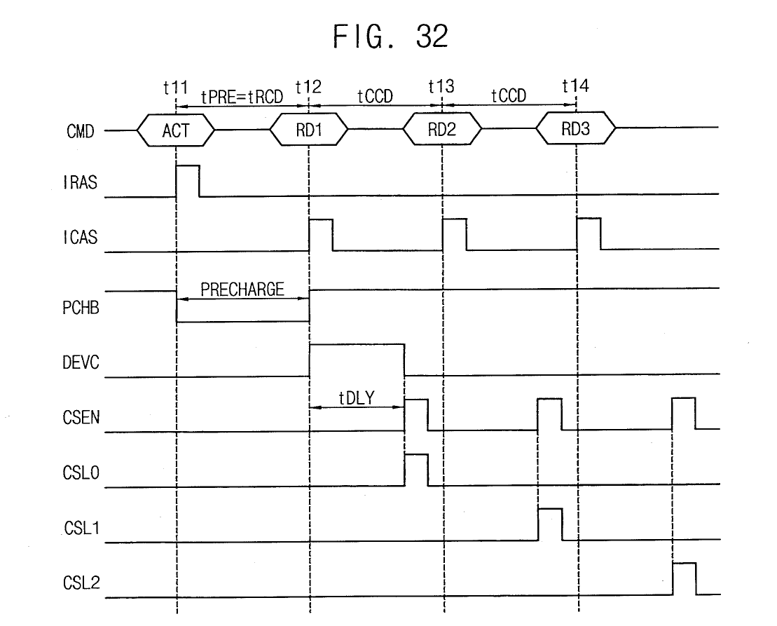

FIG. 31 is a diagram illustrating a timing control circuit that generates a precharge signal according to an example embodiment.

The timing control circuit in FIG. 31 may be included in the timing control logic 700 in FIG. 6. The timing control circuit may include a precharge control circuit 513 and a column selection enable circuit 523.

The precharge control circuit 513 may generate a precharge signal PCHB in response to an internal RAS signal IRAS and an internal CAS signal ICAS. The precharge control circuit 513 may activate the precharge signal PCHB at a time point when the internal RAS signal IRAS is activated and then deactivate the precharge signal PCHB at a time point when the internal CAS signal ICAS is activated. As described with reference to FIG. 6, the internal RAS signal IRAS may be activated at the time point when the active command ACT is received from the memory controller and the internal CAS signal ICAS may be activated at the time point when the read command RD is received from the memory controller. As a result, the precharge control circuit 513 may generate the precharge signal PCHB that is activated in response to the active command ACT and deactivated in response to the read command RD.

The column selection enable circuit 523 may generate a develop control signal DEVC and a column selection enable signal CSEN in response to the internal RAS signal IRAS and the internal CAS signal ICAS. The column selection enable circuit 523 may activate the develop control signal DEVC at a time point when the internal CAS signal ICAS is activated firstly after the internal RAS signal IRAS is activated. In addition, the column selection enable circuit 523 may deactivate the develop control signal DEVC after a predetermined delay time tDLY as illustrated in FIG. 31.

The column selection enable circuit 523 may activate the column selection enable signal CSEN at the time point when the internal CAS signal ICAS is activated. For example as described with reference to FIG. 32, the column selection enable circuit 523 may activate the column selection signal CSEN with the delay time tDLY from the activation of the internal CAS signal ICAS. The column selection enable signal CSEN may be used to control the output timing of the data bits latched in the sense amplifiers SAs as described with reference to FIG. 29, and the column selection enable signal CSEN may activated in a form of pulse train.

FIG. 32 is a timing diagram illustrating an operation of a resistive memory device according to an example embodiment.

Referring to FIGS. 6, 29, 30, 31 and 32, the command decoder 500 may activate the internal RAS signal IRAS at a time point t11 when the active command ACT is received, and activate the internal CAS signal ICAS at time points t12, t13 and t14 when the read commands RD1, RD2 and RD3 are received.

At the time point t11 when the resistive memory device 1200c receives the active command ACT, the precharge control circuit 513 activates the precharge signal PCHB in the logic low level in response to the internal RAS signal IRAS. The read sensing circuit 430 begins the precharge operation in response to the activation of the precharge signal PCHB simultaneously with respect to the bitline sensing nodes BSNs coupled to the plurality of bitlines BL0˜BLm.

At the time point t12 when the resistive memory device 1200b receives the first read command RD1, the precharge control circuit 513 deactivates the precharge signal PCHB in the logic high level in response to the internal CAS signal ICAS. The read sensing circuit 430 quits the precharge operation in response to the deactivation of the precharge signal PCHB.

In addition, at the time point t12, the column selection enable circuit 523 activates the develop control signal DEVC in the logic high level. The bitline BLi is electrically coupled to the corresponding bitline sensing node BSN in response to the activation of the develop control signal DEVC, and the read sensing circuit 430 begins the develop operation as described with reference to FIG. 10. The column selection enable circuit 523 may deactivate the develop control signal DEVC after the predetermined delay time tDLY from the time point t12. The delay time tDLY may be determined considering the develop time tDEV and the latch time tLAT as described with reference to FIG. 10.

The develop control signal DEVC is provided commonly to the plurality of bitline sensing units BLSAs in the read sensing circuit 430, and thus the bitline sensing units BLSAs may perform the page open operation.

The column selection enable circuit 523 may activate the column selection enable signal CSEN after the delay time tDLY from the activations of the internal CAS signal ICAS. As described above, the column selection enable signal CSEN may be used to control the output timing of the data bits latched by the sense amplifiers SAs, and thus the column selection enable signal CSEN may be activated in the form of pulse train as illustrated in FIG. 32.

The column selection signals CSL0, CSL1, CSL2, etc. are sequentially activated in synchronization with the column selection enable signal CSEN and the latched data bits in the sense amplifiers SAs may be provided sequentially to the local multiplexer LMUX.

As such, the read sensing circuit 430 may perform the hidden precharge operation with respect to the plurality of bitline sensing nodes BSNs during the RAS-to-CAS delay time tRCD. Thus the read speed may be increased and the reliability of the read data may be enhanced due to the increased sensing margin.

In addition, through the page open operation, the CAS-to-CAS delay time tCCD may be shorted and thus the performance of the resistive memory device may be further enhanced.

FIG. 33 is a diagram illustrating a system including a resistive memory device according to example embodiments.

Referring to FIG. 33, a system 2000 includes a memory controller 2100 and a memory device 2200. The memory device 2200 includes a DRAM interface DIF for communicating with the memory controller 2100 as described with reference to FIG. 2. The DRAM interface DIF includes control pads (or pins, ports, terminals, etc.), address pads and data pads. The memory device 2200 receives control signals such as the chip selection signal /CS, the RAS signal /RAS, the CAS signal /CAS, the write enable signal /WE, the clock enable signal CKE, etc through the control pads. The memory device 2200 receives the address signal ADD through the address pads, and receives the write data or transmits the read data through the data pads

The memory device 2200 may include a DRAM device 2210 and a resistive memory device 2220. According to the example embodiments, the resistive memory device 220 may perform the hidden precharge operation to enhance the read speed and the reliability of the read data. The DRAM device 2210 may share at least a portion of the DRAM interface DIF with the resistive memory device 2220. For example, the DRAM device 2210 and the resistive memory device 2220 may share the address pads, the data pads and/or the control pads except the pad for receiving the chip selection signal /CS. The DRAM device 2210 and the resistive memory device 2220 may be coupled respectively to the chip selection pads so that the DRAM device 2210 may be enabled in response to a first chip selection signal /CS1 and the resistive memory device 2220 may be enabled in response to a second chip selection signal /CS2.

The system including the resistive memory device 2220 according to example embodiments may be implemented with the existing DRAM interface, and thus the resistive memory device 2220 may be used as a main memory in addition to or instead of the DRAM device 2210 without excessive design change.

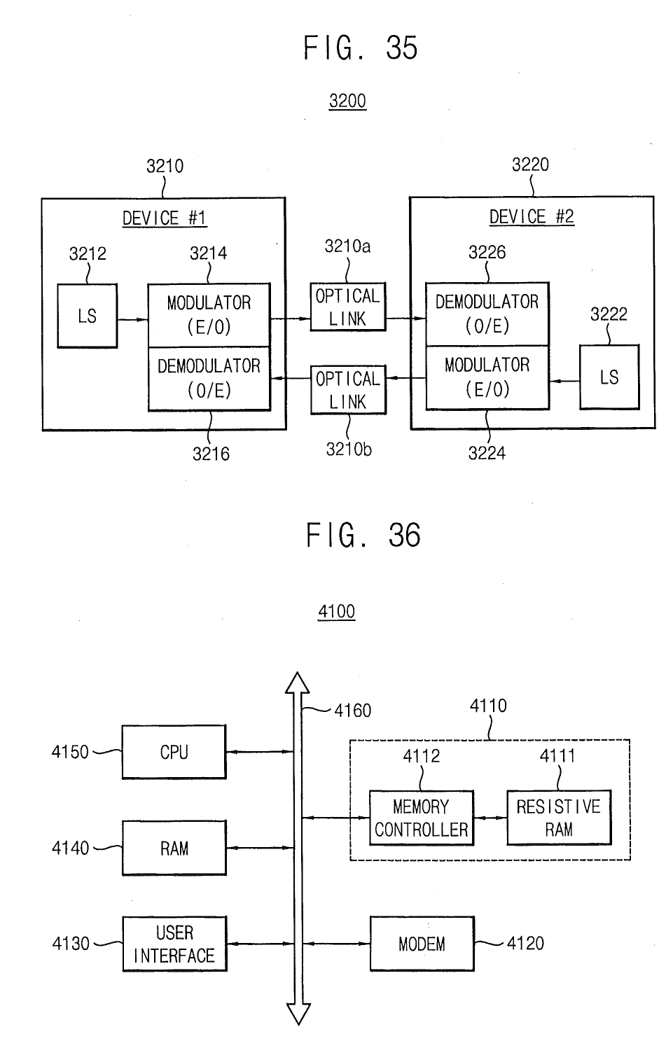

FIGS. 34 and 35 are block diagrams illustrating systems in which a memory device and a memory controller are coupled through optical links, according to example embodiments.

Referring to FIG. 34, a system may 3100 include a controller 3120, a memory device 3130 including a resistive memory, and one or more optical links 3110a and 3110b. The controller 3120 may include a control unit 3121, a first transmitting interface (CTx) 3122 and a first receiving interface (CRx) 3123. The control unit 3121 transmits a first electrical signal SN1 to the first transmitting interface 3122. The first electrical signal may include control signals, clocking signals, address signals, write data, etc to be transferred to the memory device 3130.

The first transmitting interface 3122 may include an optical modulator (E/O) and the optical modulator (E/O) may convert the first electrical signal SN1 to a first optical transmission signal OPT1 and transfer the first optical transmission signal OPT1 to the optical link 3110a. The first receiving interface 3123 may include an optical demodulator (O/E), and the optical demodulator (O/E) may convert a second optical reception signal OPT2′ to a second electrical signal SN2 and transfer the second electrical signal SN2 to the control unit 3121.

The memory device 3130 may include a memory region 3132 including resistive memory cells, a second receiving interface (MRx) 3131 and a second transmitting interface (MTx) 3133. The second receiving interface 3131 may include an optical demodulator (O/E)) and the optical demodulator (O/E) may convert a first optical reception signal OPT1′ to the first electrical signal SN1 and transfer the first electrical signal SN1 to the memory region 3122.

The memory region 3122 may write data based on the first electrical signal SN1 or transmit the read data as the second electrical signal SN2 to the second transmitting interface 3133. As described above, the memory device 3130 may perform the hidden precharge operation when reading data. The second electrical signal SN2 may include clocking signals and the read data to be transferred to the memory controller 3120. The second transmitting interface 3133 may include an optical modulator (E/O) and the optical modulator (E/O) may convert the second electrical signal SN2 to a second optical transmission signal OPT2 and transfer the second optical transmission signal OPT2 to the optical link 3110b.

Referring to FIG. 35, a system 3200 includes a first device 3210, a second device 3220 and one or more optical links 3210a and 3210b. The first and second devices 3210 and 3220 may perform serial communication with each other.

The first device 3210 may includes a first light source 3212, a first optical modulator 3214 for electrical-to-to optical (E/O) conversion, and a first optical demodulator 3216 for optical-to-electrical (O/E) conversion. The first device 3210 may include a resistive memory region (not shown) that includes a plurality of resistive memory cells and performs the hidden precharge operation as described above.

The first light source 3212 may output an optical signal having a predetermined waveform, and the first modulator 3214 may perform the E/O conversion using the output optical signal from the first light source 3212. The first demodulator 3216 receives an optical signal output from the second device 3220 and converts the received optical signal to an electrical signal.

The second device 3220 may includes a second light source 3222, a second optical modulator 3224 for electrical-to-to optical (E/O) conversion, and a second optical demodulator 3226 for optical-to-electrical (O/E) conversion. Also the second device 3220 may include a resistive memory region (not shown) that includes a plurality of resistive memory cells and performs the hidden precharge operation as described above.

The second light source 3222 may output an optical signal having a predetermined waveform, and the second modulator 3224 may perform the E/O conversion using the output optical signal from the second light source 3222. The second demodulator 3226 receives an optical signal output from the first device 3210 and converts the received optical signal to an electrical signal.

The optical links 3210a and 3210b may transfer an optical signal from the first device 3210 to the second device 3220 or vice versa.

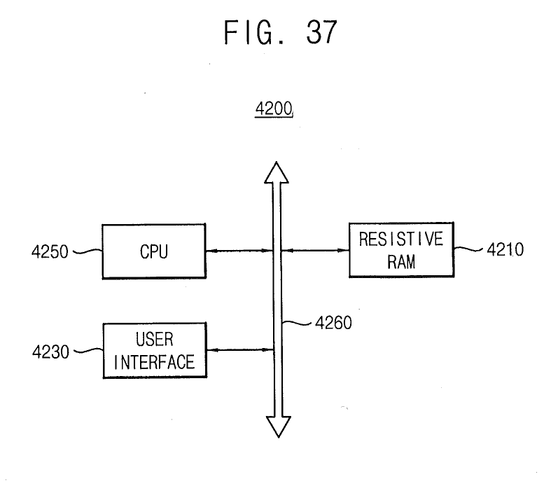

FIGS. 36 and 37 are block diagrams illustrating computing systems including a resistive memory device according to example embodiments.

Referring to FIG. 36, a computing system 4100 may be a mobile device or a desktop computer including a resistive memory device disclosed herein. The computing system 4100 may include a memory system 4110, a modem 4120, a user interface 4130, a random access memory (RAM) 4140 and a central processing unit (CPU) 4150, which are electrically coupled to a system bus 4160.

The memory system 4110 may include a resistive memory device 4111 disclosed herein and a memory controller 4112. The resistive memory device 4111 may store data processed by the CPU 4150 and/or data provided from external devices.

At least one of the resistive memory device 4111 and the RAM 4140 may be an MRAM device including the STT-MRAM cells. For example, the MRAM cells may be included in the resistive memory device 4111 for storing large amount of data and/or the RAM requiring rapid access time for system data. Even though not illustrated in FIG. 36, the computing system 4100 may further include an application chipset, an image sensor, input-output devices such as a keyboard, a monitor, etc.

Referring to FIG. 37, a computing system 4200 may be a mobile device or a desktop computer including a resistive memory device disclosed herein. The computing system 4200 may include a resistive memory device 4210 including resistive memory cells, a user interface 4230, and a central processing unit (CPU) 4250, which are electrically coupled to a system bus 4260.

For example, the STT-MRAM device is noted as a next-generation memory having advantages of low cost and high capacity of DRAM, high operational speed of SRAM and non-volatility of flash memory. Thus the resistive memory device 4210 including STT-MRAM cells may substitute all of a cache memory requiring high speed, a RAM and a storage of high capacity, which have been distinctively implemented in the conventional systems. For example, the resistive memory device 4210 may have high capacity and high operational speed and thus the computing system may have a compact configuration with smaller size.

The method of reading data according to example embodiments may be adopted in arbitrary devices and systems requiring a main memory and/or a storage device of high capacity. Particularly the resistive memory device and the associated method may be usefully adopted in portable devices such as a digital camera, a mobile phone, a smart phone, a personal digital assistant (PDA), a portable multimedia player (PMP), etc., which require higher performance and lower power consumption.

The foregoing is illustrative of example embodiments and is not to be construed as limiting thereof. Although a few example embodiments have been described, those skilled in the art will readily appreciate that many modifications are possible in the exemplary embodiments without materially departing from the novel teachings and advantages of the present inventive concepts. Accordingly, all such modifications are intended to be included within the scope of the present inventive concepts as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A resistive memory device comprising:
a memory cell array comprising a plurality of resistive memory cells coupled to a plurality of wordlines and a plurality of bitlines;
a memory interface configured to communicate with a memory controller; and
a read sensing circuit coupled to the bitlines and comprising at least one sensing node, the read sensing circuit configured to perform a precharge operation to precharge the at least one sensing node between a first time point of receiving an active command through the memory interface and a second time point of receiving a read command through the memory interface, and configured to sense data stored in the resistive memory cells to provide read data.

2. The resistive memory device of claim 1, wherein the memory interface is configured to receive a row address strobe (RAS) signal corresponding to the active command and a column address strobe (CAS) signal corresponding to the read command.

3. The resistive memory device of claim 1, further comprising:
a precharge control circuit configured to generate a precharge signal that is activated in response to the active command and deactivated in response to the read command.

4. The resistive memory device of claim 3, wherein the read sensing circuit comprises;
a local sensing node electrically coupled to a selected bitline via a column selection circuit, the selected bitline being selected among the bitlines in response to a column address;
a precharge circuit configured to precharge the local sensing node in response to the precharge signal; and
a sense amplifier configured to, after the selected bitline is electrically coupled to the local sensing node, sense a voltage or a current on the local sensing node to output the read data.

5. The resistive memory device of claim 4, wherein the read sensing circuit further comprises:
a clamp circuit coupled between the selected bitline and the local sensing node.

6. The resistive memory device of claim 4, wherein the read sensing circuit further comprises:
a bias circuit configured to apply a bias current to the local sensing node at a time point when the selected bitline is electrically coupled to the local sensing node.

7. The resistive memory device of claim 3, wherein the read sensing circuit comprises a plurality of bitline sensing units respectively coupled to the bitlines.

8. The resistive memory device of claim 7, wherein the bitline sensing units are configured to perform a page open operation in which the bitline sensing units sense and simultaneously latch a plurality of data bits that are stored in the resistive memory cells commonly coupled to a selected wordline, the selected wordline being selected among the wordlines in response to a row address.

9. The resistive memory device of claim 7, wherein each of the bitline sensing units comprises:
a bitline sensing node;
a develop switch configured to electrically couple the corresponding bitline to the bitline sensing node in response to a develop control signal;
a precharge circuit configured to precharge the bitline sensing node in response to the precharge signal; and
a sense amplifier configured to, after the selected bitline is electrically coupled to the bitline sensing node, sense a voltage or a current on the bitline sensing node to latch a bit of the read data.

10. The resistive memory device of claim 1, further comprising;
a precharge control circuit configured to generate a first precharge signal and a second precharge signal, the first precharge signal being activated in response to the active command and deactivated in response to a first read command, the first precharge signal being repeatedly activated and deactivated in response to other read commands that are sequentially received after the first read command, the second precharge signal being activated and deactivated complementarily with the first precharge signal.

11. The resistive memory device of claim 10, wherein the read sensing circuit comprises:
a first read sensing circuit configured to perform the precharge operation in response to the first precharge signal; and
a second read sensing circuit configured to perform the precharge operation in response to the second precharge signal.

12. The resistive memory device of claim 11, wherein one of the first read sensing circuit and the second read sensing circuit is selected in response to a first column selection enable signal and a second column selection enable signal that are activated complementarily with each other, and the selected one of the first read sensing circuit and the second read sensing circuit is electrically coupled to a selected bitline, the selected bitline being selected among the bitlines in response to a column address.

13. A system comprising:
a memory controller; and
a resistive memory device configured to communicate with the memory controller according to a dynamic random access memory (DRAM) standard, the resistive memory device comprising:
a memory cell array comprising a plurality of resistive memory cells coupled to a plurality of wordlines and a plurality of bitlines;
a DRAM interface configured to communicate with the memory controller; and
a read sensing circuit coupled to the bitlines and comprising at least one sensing node, the read sensing circuit configured to perform a precharge operation to precharge the at least one sensing node between a first time point of receiving an active command through the DRAM interface and a second time point of receiving a read command through the DRAM interface, and configured to sense data stored in the resistive memory cells to provide read data.

14. The system of claim 13, wherein the resistive memory device further comprises:
a precharge control circuit configured to generate a precharge signal that is activated in response to the active command and deactivated in response to the read command, and
wherein the read sensing circuit is configured to perform the precharge operation in response to the precharge signal.

15. The system of claim 13, further comprising:
a DRAM device comprising a plurality of DRAM cells.

16. The system of claim 15, wherein the DRAM device shares at least a portion of the DRAM interface with the resistive memory device.

17. The system of claim 15, wherein the DRAM device is enabled in response to a first chip selection signal and the resistive memory device is enabled in response to a second chip selection signal.

18. A method of reading data in a resistive memory device comprising a plurality of resistive memory cells coupled respectively to a plurality of wordlines and a plurality of bitlines, the method comprising:
receiving an active command and a read command from a memory controller according to a dynamic random access memory (DRAM) standard;
precharging at least one sensing node between a time point of receiving the active command and a time point of receiving the read command;
electrically coupling the at least one sensing node with at least one bitline among the plurality of bitlines; and
sensing a voltage or a current on the at least one sensing node to provide read data.

19. The method of claim 18, wherein precharging the at least one sensing node comprises:
activating a precharge signal in response to the active command; and
deactivating the precharge signal in response to the read command.

20. The method of claim 19, wherein precharging the at least one sensing node further comprises:
precharging a local sensing node in response to the precharge signal, the local sensing node being commonly coupled to the bitlines.

21. The method of claim 19, wherein precharging the at least one sensing node further comprises:
precharging a plurality of bitline sensing nodes simultaneously in response to the precharge signal, the bitline sensing nodes being coupled to the respective bitlines.

22. The method of claim 18, wherein the resistive memory device comprises a DRAM interface configured to communicate with the memory controller and the DRAM interface comprises input pads receiving a row address strobe (RAS) signal and a column address strobe (CAS) signal.
